(19) United States
(12) Patent Application Publication
(10) Pub. No.: US 2025/0169255 A1
(43) Pub. Date: May 22, 2025

(54) DISPLAY DEVICE AND METHOD FOR FABRICATING THE SAME

(71) Applicant: Samsung Display Co., LTD., Yongin-si (KR)

(72) Inventors: Kyung Rock SON, Yongin-si (KR); Sun PARK, Yongin-si (KR); Hui Won YANG, Yongin-si (KR); Jae Bok YOO, Yongin-si (KR); Jae Phil LEE, Yongin-si (KR)

(21) Appl. No.: 18/922,092

(22) Filed: Oct. 21, 2024

(30) Foreign Application Priority Data
Nov. 22, 2023 (KR) 10-2023-0162921

(51) Int. Cl. H01L 33/62; H01L 33/00; H01L 33/60

(52) U.S. Cl. CPC H10H 20/857; H10H 20/01; H10H 20/856; H10H 20/0364

(57) ABSTRACT

A display device includes a substrate including first and second pad electrodes, a bank defining a first opening, and exposing portions of the first and second pad electrodes through the first opening, an inter-electrode planarization layer between the first and second pad electrodes, a first reflective electrode extending from the bank to the inter-electrode planarization layer along the first pad electrode, a second reflective electrode extending from the bank to the inter-electrode planarization layer along the second pad electrode, an organic pattern layer in the first opening, a light-emitting element having a first contact electrode and a second contact electrode on a top surface thereof, a via layer covering the light-emitting element and defining contact holes, and first and second lead lines above the via layer and electrically connecting the first contact electrode and the first reflective electrode, and electrically connecting the second contact electrode and the second reflective electrode.

### CROSS-REFERENCE TO RELATED APPLICATION

The present application claims priority, to and the benefit of, Korean Patent Application No. 10-2023-0162921, filed on Nov. 22, 2023, in the Korean Intellectual Property Office, the entire disclosure of which is incorporated herein by reference.

### BACKGROUND

### 1. Field

The present disclosure relates to a display device and a method of manufacturing the same.

### 2. Description of the Related Art

Display devices are becoming increasingly important with the development of multimedia. In response to this, various types of display devices, such as organic light-emitting displays (OLED) and liquid crystal displays (LCD), are being used.

A device for displaying an image of a display device includes a display panel, such as an organic light-emitting display panel or a liquid crystal display panel. Among them, the light-emitting display panel may include a light-emitting element. For example, light-emitting diodes (LED) include organic light-emitting diodes (OLED) that utilize organic materials as light-emitting materials, inorganic light-emitting diodes that utilize inorganic materials as light-emitting materials, and the like.

### SUMMARY

Aspects of embodiments of the present disclosure provide a display device, and a method of manufacturing the display device, which may solve a problem of residues that may occur between pad electrodes when forming reflective electrodes.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to one or more embodiments, a display device includes a substrate including a first pad electrode and a second pad electrode, a bank defining a first opening above the substrate, and exposing a portion of the first pad electrode and a portion of the second pad electrode through the first opening, an inter-electrode planarization layer between the first pad electrode and the second pad electrode, a first reflective electrode extending from the bank to the inter-electrode planarization layer along the first pad electrode, a second reflective electrode extending from the bank to the inter-electrode planarization layer along the second pad electrode, an organic pattern layer in the first opening, a light-emitting element above the organic pattern layer, and having a first contact electrode and a second contact electrode on a top surface thereof, a via layer covering the light-emitting element, and defining contact holes, a first lead line above the via layer, and electrically connecting the first contact electrode and the first reflective electrode, and a second lead line above the via layer, and electrically connecting the second contact electrode and the second reflective electrode.

The inter-electrode planarization layer and the bank may have a same thickness.

The inter-electrode planarization layer and the bank may include a same material.

The inter-electrode planarization layer and the bank may include a light-blocking material.

The first pad electrode and the second pad electrode may be spaced apart from each other on a same plane, and may protrude outwardly from the light-emitting element in plan view.

The inter-electrode planarization layer may have a same height as the first pad electrode and the second pad electrode.

A height of the inter-electrode planarization layer may be greater than a height of the first pad electrode and the second pad electrode.

A top surface of the inter-electrode planarization layer may contact the organic pattern layer, wherein a roughness of the top surface of the inter-electrode planarization layer is greater than a roughness of another surface of the inter-electrode planarization layer.

The light-emitting element may include a third semiconductor layer contacting the organic pattern layer, a second semiconductor layer, an active layer, a first semiconductor layer, and an element-insulating layer, wherein the element-insulating layer surrounds the third semiconductor layer, the second semiconductor layer, the active layer, the first semiconductor layer, and the top surface of the light-emitting element, and defines a second opening and a third opening, wherein the first contact electrode is electrically connected to the first semiconductor layer through the second opening, and wherein the second contact electrode is electrically connected to the second semiconductor layer through the third opening.

A width of the organic pattern layer may be greater than a width of the light-emitting element.

The organic pattern layer may overlap the inter-electrode planarization layer, does not overlap the bank, and directly contacts the inter-electrode planarization layer.

The display device may further include a partition wall above the via layer, the first lead line, and the second lead line, and defining a light-emitting area, and a wavelength conversion layer in the light-emitting area, and filling the contact holes in the via layer.

The display device may further include a capping layer, an overcoat layer, and a color filter layer sequentially above the wavelength conversion layer and the partition wall.

According to one or more embodiments, a method of manufacturing display device includes providing a substrate on which a first pad electrode and a second pad electrode are located, forming a bank above the substrate, the bank defining a first opening exposing a portion of the first pad electrode and a portion of the second pad electrode, forming an inter-electrode planarization layer above the substrate between the first pad electrode and the second pad electrode, forming a first reflective electrode extending from the bank to the inter-electrode planarization layer along the first pad electrode, forming a second reflective electrode extending from the bank to the inter-electrode planarization layer along the second pad electrode, applying an organic pattern material layer in the first opening, placing a light-emitting element on the organic pattern material layer, curing the organic pattern material layer to form an organic pattern layer, and to bond the light-emitting element to the organic pattern layer, forming a via layer covering the light-emitting element, and defining contact holes, forming a first lead line above the via layer to electrically connect a first contact electrode and the first reflective electrode, and forming a second lead line above the via layer to electrically connect a second contact electrode and the second reflective electrode.

Forming the bank and forming the inter-electrode planarization layer may include coating an organic material layer above the substrate, and etching the organic material layer to form the bank and the inter-electrode planarization layer by using a mask.

The organic material layer may include a light-blocking material.

Coating the organic material layer may include applying the organic material layer to a same thickness as the first pad electrode and the second pad electrode.

The method may further include performing a descum or ashing process on a top surface of the bank and the inter-electrode planarization layer to increase a roughness of the top surface of the bank and the inter-electrode planarization layer.

The light-emitting element may include a third semiconductor layer, a second semiconductor layer, an active layer, and a first semiconductor layer stacked sequentially, wherein the light-emitting element includes an element-insulating layer, wherein the element-insulating layer surrounds the third semiconductor layer, the second semiconductor layer, the active layer, the first semiconductor layer, and a top surface of the light-emitting element, and defines a second opening and a third opening, wherein the first contact electrode is electrically connected with the first semiconductor layer through the second opening, and wherein the second contact electrode is electrically connected with the second semiconductor layer through the third opening.

The method may further include forming a partition wall above the via layer, the first lead line, and the second lead line, and defining a light-emitting area, forming a wavelength conversion layer in the light-emitting area, and forming an overcoat layer and a color filter layer sequentially arranged above the partition wall and the wavelength conversion layer.

The display device according to one or more embodiments may solve the problem of residues that may occur between pad electrodes when forming reflective electrodes, and has a degree of freedom in selecting an etching chemical solution. Light leakage to the bottom of the light-emitting element may be reduced or prevented.

However, the effects of the present disclosure are not limited to the aforementioned aspects, and various other aspects are included in the present specification.

### BRIEF DESCRIPTION OF THE DRAWINGS

FIG. 1 is a perspective view illustrating a display device according to one or more embodiments.

FIGS. 2 and 3 are plan views illustrating a display device according to one or more embodiments.

FIG. 4 is a circuit diagram illustrating a first sub-pixel of a display panel according to one or more embodiments.

FIG. 5 is a circuit diagram illustrating a first sub-pixel of a display panel according to one or more other embodiments.

FIG. 6 is a schematic cross-sectional view of a display device according to one or more embodiments.

FIG. 7 is an enlarged view schematically illustrating the first light-emitting area described with reference to FIG. 6.

FIG. 8 is an enlarged view of the light-emitting element described with reference to FIG. 7.

FIG. 9 is an enlarged view schematically illustrating the first light-emitting area described with reference to FIG. 6 according to one or more other embodiments.

FIG. 10 is an enlarged view schematically illustrating the first light-emitting area described with reference to FIG. 6 according to one or more other embodiments.

FIGS. 11 to 26 are diagrams to illustrate a method of manufacturing a display device according to one or more embodiments.

FIG. 27 is a diagram schematically showing a virtual reality device including a display device according to one or more embodiments;

FIG. 28 is a diagram schematically showing a smart device including a display device according to one or more embodiments;

FIG. 29 is a diagram schematically showing a vehicle including a display device according to one or more embodiments; and

FIG. 30 is a diagram schematically showing a transparent display device including a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

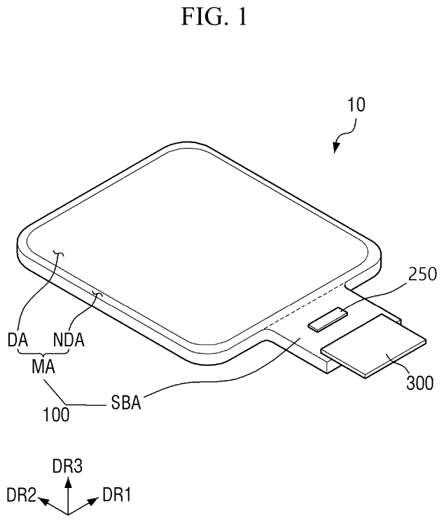

FIG. 1 is a perspective view illustrating a display device according to one or more embodiments.

Referring to FIG. 1, a display device 10 is a device for displaying video or still images, such as mobile phones, smart phones, tablet personal computers, and portable electronic devices, such as smart watches, watch phones, mobile communication terminals, electronic notebooks, e-books, portable electronic devices, such as portable multimedia players (PMP), navigation, and ultra mobile PCs (UMPC), as well as display screens for a variety of products, such as televisions, laptops, monitors, billboards, and the internet of things (IOT).

The display device 10 may be a light-emitting display device, such as an organic light-emitting display device utilizing an organic light-emitting diode, a quantum dot light-emitting display device including a quantum dot light-emitting layer, an inorganic light-emitting display device including an inorganic semiconductor, and a miniaturized light-emitting display device utilizing a micro or nano light-emitting diode (micro LED or nano LED). Hereinafter, the description focuses on the fact that the display device 10 is a micro light-emitting display device, but the present disclosure is not limited thereto. On the other hand, a micro light-emitting diode referred to as a light-emitting element in the following for convenience of explanation.

The display device 10 includes a display panel 100, a display-driving circuit 250, and a circuit board 300.

The display panel 100 may be formed as a rectangular-shaped plane having a short side in the first direction DR1, and a long side in the second direction DR2 that crosses the first direction DR1. A corner where the short side in the first direction DR1 and the long side in the second direction DR2 meet may be rounded to have a curvature (e.g., predetermined curvature), or may be formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends, and may include curved portions with a constant curvature or a changing curvature. Additionally, the display panel 100 may be formed to be flexible, such as to be able to be bent, curved, bent, folded, or rolled.

The substrate SUB of the display panel 100 may include a main area MA and a sub-area SBA.

The main area MA may include a display area DA that displays an image and a non-display area NDA that is a peripheral area of the display area DA. The display area DA may include a plurality of pixels that display an image. For example, the pixel may include a first sub-pixel that emits first light, a second sub-pixel that emits second light, and a third sub-pixel that emits third light.

The sub-area SBA may protrude from one side of the main area MA in the second direction DR2. Although FIG. 1 illustrates the sub-area SBA being unfolded, the sub-area SBA may be bent, and in this case, may be located on (e.g., beneath) the bottom surface of the display panel 100. When the sub-area SBA is bent, it may overlap the main area MA in the third direction DR3, which is the thickness direction of the display panel 100. The display-driving circuit 250 may be located in the sub-area SBA.

The display-driving circuit 250 may generate signals and voltages for driving the display panel 100. The display-driving circuit 250 may be formed as an integrated circuit (IC), and may be attached to the display panel 100 using a chip-on-glass (COG) method, a chip-on-plastic (COP) method, or an ultrasonic bonding method but is not limited thereto. For example, the display-driving circuit 250 may be attached to the circuit board 300 using a chip-on-film (COF) method.

The circuit board 300 may be attached to one end of the sub-area SBA of the display panel 100. As such, the circuit board 300 may be electrically connected to the display panel 100 and to the display-driving circuit 250. The display panel 100 and the display-driving circuit 250 may receive digital video data, timing signals, and driving voltages through the circuit board 300. The circuit board 300 may be a flexible film, such as a flexible printed circuit board, a printed circuit board, or a chip on film.

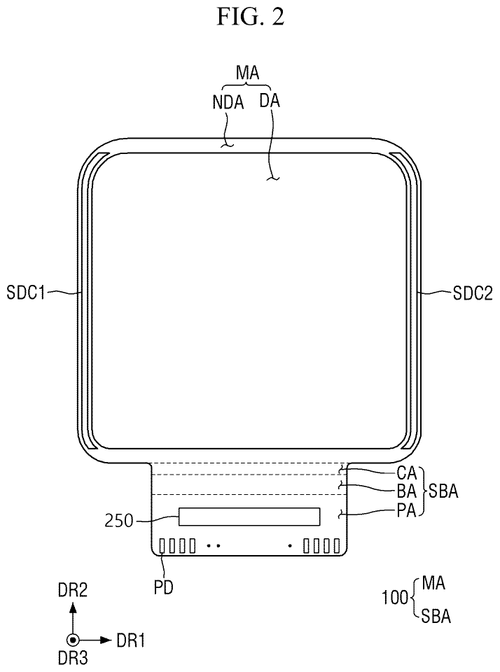

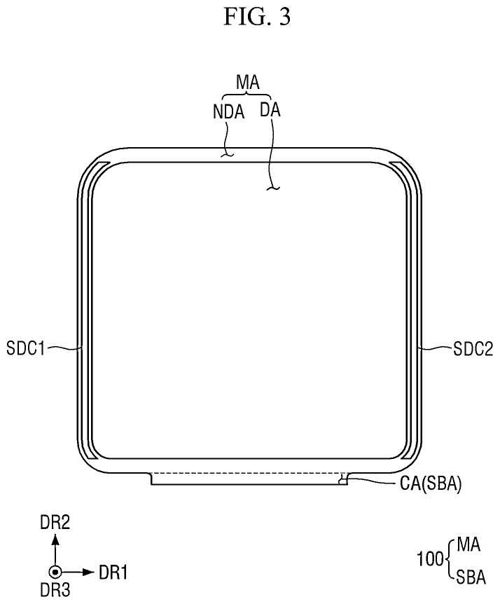

FIGS. 2 and 3 are plan views illustrating a display device according to one or more embodiments. FIG. 3 illustrates that the sub-area SBA is bent.

Referring to FIGS. 2 and 3, the display panel 100 may include the main area MA and the sub-area SBA.

The main area MA may include the display area DA that displays an image, and the non-display area NDA that is a peripheral area of the display area DA. The display area DA may occupy most of the main area MA. The display area DA may be placed in the center of the main area MA.

The non-display area NDA may be placed adjacent to the display area DA. The non-display area NDA may be an area outside the display area DA. The non-display area NDA may be arranged to surround the display area DA (e.g., in plan view). The non-display area NDA may be an edge area of the display panel 100.

A first scan driver SDC1 and a second scan driver SDC2 may be located in the non-display area NDA. The first scan driver SDC1 is located on one side (for example, the left side) of the display panel 100, and the second scan driver SDC2 is located on the other side (for example, the right side) of the display panel 100. However, it is not limited thereto. Each of the first scan driver SDC1 and the second scan driver SDC2 may be electrically connected to the display-driving circuit 250 through scan fan-out lines. Each of the first scan driver SDC1 and the second scan driver SDC2 may receive a scan control signal from the display-driving circuit 250, may generate scan signals according to the scan control signal, and may output them to the scan lines.

The sub-area SBA may protrude from one side of the main area MA in the second direction DR2. The length of the sub-area SBA in the second direction DR2 may be less than the length of the main area MA in the second direction DR2. The length of the first direction DR1 of the sub-area SBA may be less than the length of the first direction DR1 of the main area MA, or may be substantially equal to the length of the first direction DR1 of the main area MA. The sub-area SBA may be curved, and may be located at the lower portion of the display panel 100. In this case, the sub-area SBA may overlap the main area MA in the third direction DR3.

The sub-area SBA may include a connection area CA, a pad area PA, and a bending area BA.

The connection area CA is an area protruding from one side of the main area MA in the second direction DR2. One side of the connection area CA may contact the non-display area NDA of the main area MA, and the other side of the connection area CA may contact the bending area BA.

The pad area PA is an area where the pads PD and the display-driving circuit 250 are located. The display-driving circuit 250 may be attached to the driving pads of the pad area PA using a conductive adhesive member, such as an anisotropic conductive film. The circuit board 300 may be attached to the pads PD of the pad area PA using a conductive adhesive member, such as an anisotropic conductive film. One side of the pad area PA may contact the bending area BA.

The bending area BA is a bent area. When the bending area BA is bent, the pad area PA may be located below the connection area CA and below the main area MA. The bending area BA may be located between the connection area CA and the pad area PA. One side of the bending area BA may contact the connection area CA, and the other side of the bending area BA may contact the pad area PA.

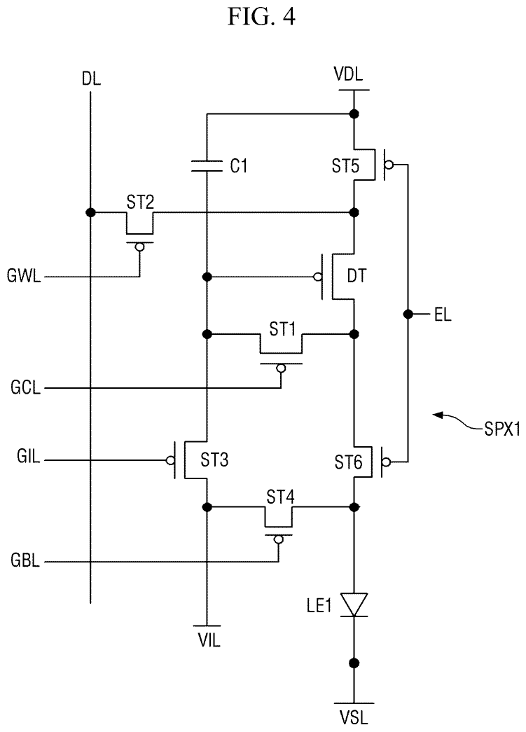

FIG. 4 is a circuit diagram illustrating a first sub-pixel of a display panel according to one or more embodiments.

Referring to FIG. 4, the first sub-pixel SPX1 according to one or more embodiments may be connected to scan lines GWL, GIL, GCL, and GBL, an emission line EL, and a data line DL. For example, the first sub-pixel SPX1 may be connected to the write scan line GWL, the initialization scan line GIL, the control scan line GCL, the bias scan line GBL, the emission line EL, and the data line DL.

The first sub-pixel SPX1 according to one or more embodiments includes a driving transistor DT, switch elements, a capacitor C1, and a first light-emitting element LE1. The switch elements may include first to sixth transistors ST1, ST2, ST3, ST4, ST5, and ST6.

The driving transistor DT includes a gate electrode, a first electrode, and a second electrode. The driving transistor DT controls the drain-source current (hereinafter referred to as “driving current”) flowing between the first electrode and the second electrode according to the data voltage applied to the gate electrode.

The first light-emitting element LE1 may be a micro light-emitting diode. The first light-emitting element LE1 emits light according to the driving current. The amount of light emitted from the first light-emitting element LE1 may be proportional to the driving current. An anode electrode of the first light-emitting element LE1 may be connected to the first electrode of the fourth transistor ST4 and to the second electrode of the sixth transistor ST6, and a cathode electrode of the first light-emitting element LE1 may be connected to a second power supply line VSL to which the second power voltage is applied.

The capacitor C1 is formed between the gate electrode of the driving transistor DT and the first power supply line VDL to which the first power supply voltage is applied. The first power supply voltage may be at a higher level than the second power supply voltage. One electrode of the capacitor C1 may be connected to the gate electrode of the driving transistor DT, and the other electrode may be connected to the first power supply line VDL.

As shown in FIG. 4, the first to sixth transistors ST1, ST2, ST3, ST4, ST5, and ST6 and the driving transistor DT may all be formed as p-type MOSFET. In this case, the active layer of each of the first to sixth transistors ST1, ST2, ST3, ST4, ST5, and ST6 and the driving transistor DT may be formed of polysilicon or oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5, and ST6 are formed as p-type MOSFET, they may be turned on when a scan signal of the gate low voltage or an emission signal are applied to the control scan line GCL, the initialization scan line GIL, the write scan line GWL, the bias scan line GBL, and the emission line EL, respectively. One electrode of the third transistor ST3 and one electrode of the fourth transistor ST4 may be connected to an initialization voltage line VIL.

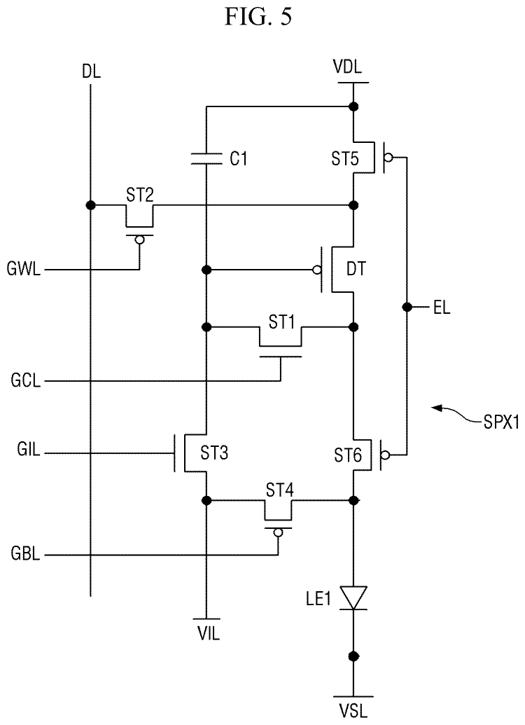

FIG. 5 is a circuit diagram illustrating a first sub-pixel of a display panel according to one or more other embodiments.

Referring to FIG. 5, the driving transistor DT, the second transistor ST2, the fourth transistor ST4, the fifth transistor ST5, and the sixth transistor ST6 are formed of p-type MOSFET, and the first transistor ST1 and the third transistor ST3 may be formed as n-type MOSFET. The active layer of each of the driving transistor DT, the second transistor ST2, the fourth transistor ST4, the fifth transistor ST5, and the sixth transistor ST6 formed as the p-type MOSFET may be formed of polysilicon, and the active layer of each of the first transistor ST1 and the third transistor ST3 formed as the n-type MOSFET may be formed of the oxide semiconductor. In this case, transistors formed of polysilicon and transistors formed of oxide semiconductors may be arranged in different layers.

Because the first transistor ST1 and the third transistor ST3 are formed as n-type MOSFET, the first transistor ST1 may be turned on when a control scan signal with a gate high voltage is applied to the control scan line GCL, and the third transistor ST3 may be turned on when an initialization scan signal is applied to the initialization scan line GIL. In comparison, the second transistor ST2, the fourth transistor ST4, the fifth transistor ST5, and the sixth transistor ST6 are formed as p-type MOSFET, so they may be turned on when a scan signal with a gate low voltage and an emission signal are applied to the write scan line GWL, the bias scan line GBL, and the emission line EL, respectively.

Alternatively, the fourth transistor ST4 in FIG. 4 may be formed of the n-type MOSFET. In this case, the active layer of each fourth transistor ST4 may be formed of the oxide semiconductor. When the fourth transistor ST4 is formed of n-type MOSFET, it may be turned on when a bias scan signal of a gate high voltage is applied to the bias scan line GBL.

Alternatively, in one or more embodiments, the first to sixth transistors ST1, ST2, ST3, ST4, ST5, and ST6 and the driving transistor DT may all be formed as n-type MOSFET.

Meanwhile, the circuit diagram of the second sub-pixel and the third sub-pixel according to one or more embodiments are substantially the same as the circuit diagram of the first sub-pixel SPX1 described in conjunction with FIGS. 4 and 5, so a description thereof will be omitted.

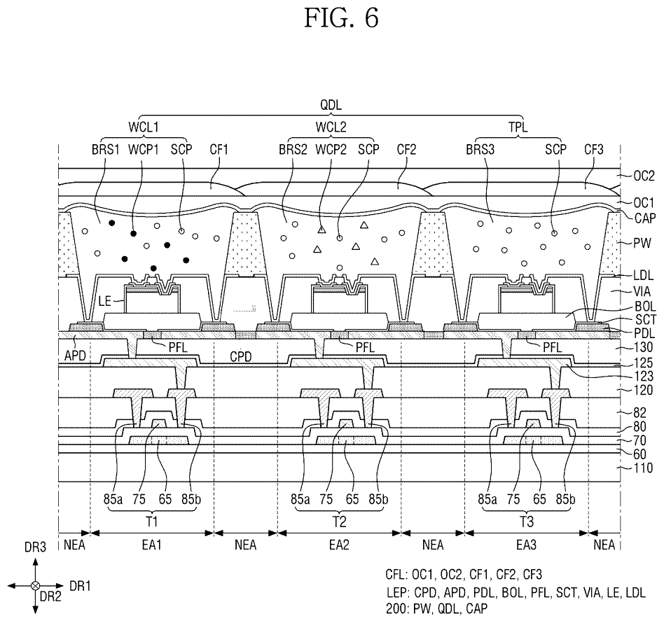

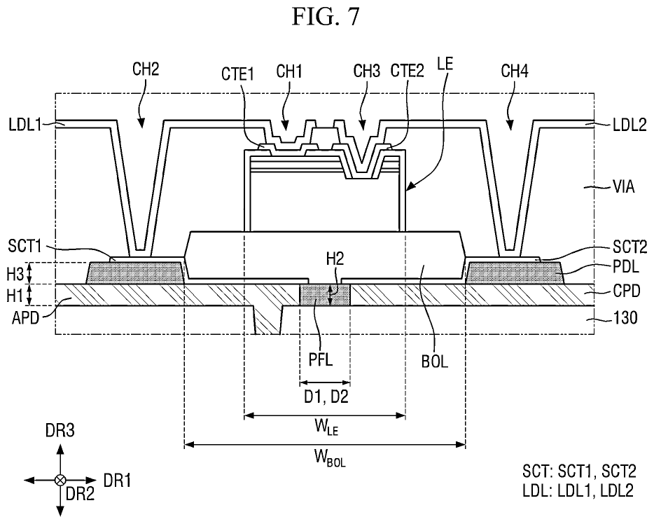

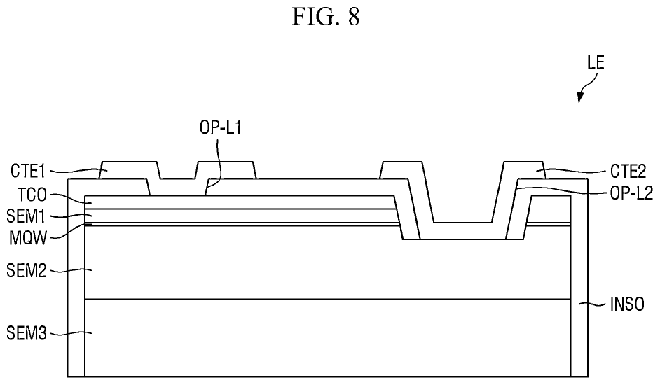

FIG. 6 is a schematic cross-sectional view of a display device according to one or more embodiments. FIG. 7 is an enlarged view schematically illustrating the first light-emitting area described with reference to FIG. 6. FIG. 8 is an enlarged view of the light-emitting element described with reference to FIG. 7.

Referring to FIGS. 6 and 8, the display device 10 may include a substrate 110, a light-emitting element portion LEP, a wavelength controller 200, and a color filter layer CFL.

The substrate 110 may be an insulating substrate. The substrate 110 may include a transparent material. For example, the substrate 110 may include a transparent insulating material, such as glass, quartz, or the like. The substrate 110 may be a rigid substrate. However, the substrate 110 is not limited thereto and may include a plastic, such as polyimide, or the like. Also, the substrate 110 may have flexible characteristics that allow it to be warped, bent, folded, or rolled. A plurality of emitting areas EA1, EA2, and EA3 and non-emitting areas NEA may be defined on the substrate 110.

Switching elements T1, T2, and T3 may be located on the substrate 110. In one or more embodiments, the first switching element T1 may be located in the first light-emitting area EA1 of the substrate 110, the second switching element T2 may be located in the second light-emitting area EA2, and the third switching element T3 may be located in the third light-emitting area EA3. However, it is not limited to this, and at least one of the first switching element T1, the second switching element T2, and the third switching element T3 may be located in the non-emitting area NEA in other embodiments.

In one or more embodiments, the first switching element T1, the second switching element T2, and the third switching element T3 may each be a thin film transistor including an amorphous silicon, polysilicon, or oxide semiconductor. In one or more embodiments, there may be a plurality of signal lines (e.g., gate lines, data lines, power supply lines, etc.) further located on the substrate 110 that carry signals to each switching element.

Each switching element T1, T2, and T3 may include a semiconductor layer 65, a gate electrode 75, a source electrode 85a, and a drain electrode 85b.

For example, a buffer layer 60 may be located on the substrate 110. The buffer layer 60 may cover a front side of the substrate 110. The buffer layer 60 may include a silicon nitride, a silicon oxide, or a silicon oxynitride, and may be a single layer or a double layer thereof.

The semiconductor layer 65 may be located on the buffer layer 60. The semiconductor layer 65 may form a channel of each of the switching elements T1, T2, and T3. The semiconductor layer 65 may include amorphous silicon, polycrystalline silicon, or an oxide semiconductor. In one example, the oxide semiconductor, for example, may include a binary compound (ABx), a ternary compound (ABxCy), or a quaternary compound (ABxCyDz) containing indium, zinc, gallium, tin, titanium, aluminum, hafnium (Hf), zirconium (Zr), magnesium (Mg), and/or the like. In one or more embodiments, the semiconductor layer 65 may include indium tin zinc oxide (IGZO).

A gate-insulating layer 70 may be located on the semiconductor layer 65. The gate-insulating layer 70 may include a silicon compound, a metal oxide, or the like. For example, the gate-insulating layer 70 may include a silicon oxide, a silicon nitride, a silicon oxynitride, an aluminum oxide, a tantalum oxide, a hafnium oxide, a zirconium oxide, a titanium oxide, and/or the like. In one or more embodiments, the gate-insulating layer 70 may include a silicon oxide.

The gate electrode 75 may be located on the gate-insulating layer 70. The gate electrode 75 may overlap the semiconductor layer 65. The gate electrode 75 may include a conductive material. The gate electrode 75 may include a metal oxide, such as ITO, IZO, ITZO, In₂O₃, or a metal, such as copper (Cu), titanium (Ti), aluminum (Al), molybdenum (Mo), tantalum (Ta), calcium (Ca), chromium (Cr), magnesium (Mg), or nickel (Ni). For example, the gate electrode 75 may be formed of a Cu/Ti double layer in which an upper layer of copper is stacked on a lower layer of titanium, but is not limited thereto.

A first interlayer insulating layer 80 and a second interlayer insulating layer 82 may be located on the gate electrode 75. The first interlayer insulating layer 80 may be directly located on the gate electrode 75, and the second interlayer insulating layer 82 may be directly located on the first interlayer insulating layer 80. The first interlayer insulating layer 80 and the second interlayer insulating layer 82 each may include an inorganic insulating material, such as a silicon oxide, a silicon nitride, a silicon oxynitride, a hafnium oxide, an aluminum oxide, a titanium oxide, a tantalum oxide, a zinc oxide, and/or the like. However, it is not limited thereto, and the second interlayer insulating layer 82 may include an organic insulating material capable of flattening/planarizing a lower step. Two interlayer insulating layers, the first interlayer insulating layer 80 and the second interlayer insulating layer 82, are illustrated and described, but the present disclosure is not limited thereto, and only one interlayer insulating layer may be located.

The source electrode 85a and a drain electrode 85b may be located on the first interlayer insulating layer 80. The source electrode 85a and the drain electrode 85b may be connected to the semiconductor layer 65 through respective contact holes penetrating the first interlayer insulating layer 80, the second interlayer insulating layer 82, and the gate-insulating layer 70. The source electrode 85a and the drain electrode 85b may include metal oxides, such as ITO, IZO, ITZO, In₂O₃, or metals, such as copper (Cu), titanium (Ti), aluminum (Al), molybdenum (Mo), tantalum (Ta), calcium (Ca), chromium (Cr), magnesium (Mg), and/or nickel (Ni). For example, the source electrode 85a and the drain electrode 85b may be formed of a Cu/Ti double layer in which an upper layer of copper is stacked on a lower layer of titanium, but is not limited thereto.

A first planarization layer 120 may be located on the first switching element T1, on the second switching element T2, and on the third switching element T3. The first planarization layer 120 may include an organic material. For example, the first planarization layer 120 may include acrylic-based resin, epoxy-based resin, imide-based resin, ester-based resin, or the like. In one or more embodiments, the first planarization layer 120 may include a positive photosensitive material or a negative photosensitive material.

A pixel connection electrode 123 may be located on the first planarization layer 120. A pixel connection electrode 123 corresponds to each of the first switching element T1, the second switching element T2, and the third switching element T3, and may be electrically connected to them. The pixel connection electrode 123 may connect pixel electrodes to the switching elements T1, T2, and T3 described above. The pixel connection electrode 123 may contact the switching elements T1, T2, and T3 through a contact hole penetrating the first planarization layer 120.

A protective layer 125 may be formed on the first planarization layer 120 and the pixel connection electrode 123. The protective layer 125 may be formed of an inorganic film, for example, a silicon nitride layer, a silicon oxynitride layer, a silicon oxide layer, a titanium oxide layer, or an aluminum oxide layer. The protective layer 125 may be omitted.

A second planarization layer 130 may be located on the protective layer 125. The second planarization layer 130 flattens the lower-level difference, and may include the same material as the first planarization layer 120 described above.

The light-emitting element portion LEP may be located on the second planarization layer 130. The light-emitting element portion LEP may include a first pad electrode APD, a second pad electrode CPD, an inter-electrode planarization layer PFL, a reflective electrode SCT, a bank PDL, an organic pattern layer BOL, a plurality of light-emitting elements LE, a via layer VIA, and a lead line LDL.

The first pad electrode APD may be supplied with a first power supply voltage that is a low potential voltage. For example, the first pad electrode APD may be a cathode electrode, but is not limited thereto. The second pad electrode CPD may be directly connected to the pixel connection electrode 123 through a contact hole penetrating the second planarization layer 130, and may be electrically connected to each of the switching elements T1, T2, and T3 through the pixel connection electrode 123. The second pad electrode CPD may be an anode electrode. The first pad electrode APD and the second pad electrode CPD may be formed as a single layer or multiple layers of any one of molybdenum (Mo), aluminum (Al), chromium (Cr), gold (Au), titanium (Ti), nickel (Ni), neodymium (Nd), and/or copper (Cu), or an alloy thereof. In some embodiments, the first pad electrode APD and the second pad electrode CPD may have a two-layer structure of Ti/Al or a three-layer structure of Ti/Al/Ti.

The first pad electrode APD and the second pad electrode CPD may be arranged to be spaced apart from each other on the same plane and may be arranged to protrude outward from the light-emitting element LE. The first pad electrode APD and the second pad electrode CPD may be arranged to be spaced apart by a first separation distance D1. The first separation distance D1 may be about 4 μm to about 6 μm. A height H1 of the first pad electrode APD and the second pad electrode CPD may be about 6000 Å to about 7000 Å.

The inter-electrode planarization layer PFL may be located between the first pad electrode APD and the second pad electrode CPD (e.g., in plan view). As shown in FIG. 7, a width D2 of the inter-electrode planarization layer PFL (e.g., in plan view) may be the same as the first separation distance D1 between the first pad electrode APD and the second pad electrode CPD. Therefore, the width D2 of the inter-electrode planarization layer PFL may be about 4 μm to 6 μm. A height (e.g., a thickness) H2 of the inter-electrode planarization layer PFL may be the same as the height (e.g., thickness) H1 of the first pad electrode APD and the second pad electrode CPD. The height H2 of the inter-electrode planarization layer PFL may be about 6000 Å to about 7000 Å. Meanwhile, the height H2 of the inter-electrode planarization layer PFL may be the same as a height (e.g., thickness) H3 of the bank PDL. Accordingly, the height H3 of the bank PDL may be about 6000 Å to about 7000 Å.

The inter-electrode planarization layer PFL may overlap the light-emitting element LE in the thickness direction.

The inter-electrode planarization layer PFL is formed of an organic film, such as acrylic-based resin, epoxy-based resin, phenolic-based resin, polyamide-based resin, polyimide-based resin, or the like. The inter-electrode planarization layer PFL may further include a light-blocking material, and the light-blocking material may include a dye or pigment having light-blocking properties.

The bank PDL may be located on the second planarization layer 130, the first pad electrode APD, and the second pad electrode CPD. The bank PDL is not formed to cover both the first pad electrode APD and the second pad electrode CPD. The bank PDL may include/define an opening to expose at least a portion of the first pad electrode APD and at least a portion of the second pad electrode CPD through the opening. The bank PDL may cover the edges of the first pad electrode APD and the second pad electrode CPD. The bank PDL may include an inclined portion that overlaps the edges of the first pad electrode APD and the second pad electrode CPD and has a slope (e.g., predetermined slope), and may also include a flat portion that extends from the inclined portion and has a flat plane.

The bank PDL may be formed in a spaced apart area between a pair of adjacent first and second pad electrodes APD and CPD formed on the second planarization layer 130.

The bank PDL may be formed of the same material as the inter-electrode planarization layer PFL. The bank PDL may be formed from an organic film, such as acrylic-based resin, epoxy-based resin, phenolic-based resin, polyamide-based resin, polyimide-based resin, or the like. The inter-electrode planarization layer PFL may further include a light-blocking material, which may include a dye or pigment having shielding properties.

The reflective electrode SCT may be located on the bank PDL, the first pad electrode APD, and the second pad electrode CPD. The reflective electrode SCT may include a first reflective electrode SCT1 and a second reflective electrode SCT2. For example, the first reflective electrode SCT1 is located on the first pad electrode APD, and the first pad electrode APD and the first reflective electrode SCT1 are electrically connected to each other as they are formed of a conductive material. The second reflective electrode SCT2 is located on the second pad electrode CPD, and the second pad electrode CPD and the second reflective electrode SCT2 are electrically connected to each other because they are formed of conductive materials. The first reflective electrode SCT1 and the second reflective electrode SCT2 are arranged to be spaced apart from each other, and each end of the first reflective electrode SCT1 and the second reflective electrode SCT2 may be located on the top surface of the bank PDL along the bank PDL. One end of each of the first and second reflective electrodes SCT1 and SCT2 may be located on a planar portion of the bank PDL. Accordingly, the reflective electrode SCT may have a step due to the bank PDL. The other ends of the first and second reflective electrodes SCT1 and SCT2 may be located on the inter-electrode planarization layer PFL. The other ends of the first and second reflective electrodes SCT1 and SCT2 may be spaced apart from each other on the inter-electrode planarization layer PFL.

The reflective electrode SCT may include a metal material with high reflectivity of light. For example, the reflective electrode SCT may include aluminum or silver, or may be an alloy thereof. The reflective electrode SCT may be formed as a single layer but may also be formed as a multilayer. For example, the reflective electrode SCT may be formed of a multilayer structure of ITO/Ag/ITO. The ITO/Ag/ITO of the reflective electrode SCT may be formed to a thickness of about 50 Å/about 850 Å/about 115 Å, respectively, but is not limited thereto.

The organic pattern layer BOL may be located in the opening of the bank PDL. The organic pattern layer BOL may be located on the reflective electrode SCT and the inter-electrode planarization layer PFL. The organic pattern layer BOL may overlap at least a portion of the first pad electrode APD and at least a portion of the second pad electrode CPD.

The organic pattern layer BOL may be located in an island pattern shape in each light-emitting area EA1, EA2, and EA3. For example, the organic pattern layers BOL located in each light-emitting area EA1, EA2, and EA3 may be arranged to be spaced apart from the organic pattern layers BOL located in adjacent light-emitting areas EA1, EA2, and EA3.

The thickness of the plurality of organic pattern layers BOL may be the same as or thicker than the thickness of the bank PDL. For example, the thickness of the organic pattern layer BOL may be about 1.5 μm to about 2.1 μm but is not limited thereto. A width W_{BOL} of the organic pattern layer BOL may be formed to be wider than a width W_{LE} of the light-emitting element LE, but is not limited thereto.

The organic pattern layer BOL may include an organic material. The organic material may be, for example, but is not limited to, a photosensitive organic insulating material. Further, the organic material may include epoxy-based resin, acrylic-based resin, cardo-based resin, or imide-based resin. The organic pattern layer BOL may be formed through various methods, such as an organic imprinting method, an inkjet printing method, an electro-spray method, or a stamping method.

It is difficult to replace the organic pattern layer BOL with an anisotropic conductive film (ACF) in a high-resolution display panel, such as the display device 10 in one or more embodiments.

The light-emitting element LE may be located on the organic pattern layer BOL. The light-emitting elements LE may be inorganic light-emitting elements made of an inorganic material, such as GaN.

The light-emitting elements LE may be located in each of the first light-emitting area EA1, the second light-emitting area EA2, and the third light-emitting area EA3. The light-emitting element LE is a lateral light-emitting element, such that the length of the first direction DR1, the length of the second direction DR2, and the length of the third direction DR3 may each be from a few to several hundred micrometers. For example, the light-emitting element LE may be about 10 μm×25 μm but is not limited thereto. The thickness of the light-emitting element LE may be about 5.5 μm but is not limited thereto.

Referring to FIG. 8, the light-emitting element LE may be a light-emitting structure including a third semiconductor layer SEM3, a second semiconductor layer SEM2, an active layer MQW, a first semiconductor layer SEM1, a transparent conductive layer TCO, a first contact electrode CTE1, and a second contact electrode CTE2.

The third semiconductor layer SEM3 may include an undoped semiconductor, and may be a material that is not doped as n-type or p-type. In one or more embodiments, a third semiconductor material layer SEM3 may be at least one of undoped InAlGaN, GaN, AlGaN, InGaN, AlN, or InN, but is not limited thereto.

The second semiconductor layer SEM2 may be located on the third semiconductor layer SEM3. The second semiconductor layer SEM2 may be doped with a second conductive dopant, such as Si, Ge, Sn, or the like. For example, the second semiconductor layer SEM2 may be n-GaN doped with n-type Si. The thickness of the second semiconductor layer SEM2 may be about 500 nm to about 1 μm.

The active layer MQW may be located on the second semiconductor layer SEM2. The active layer MQW may emit light by combining electron-hole pairs according to electrical signals applied through the first semiconductor layer SEM1 and the second semiconductor layer SEM2. The active layer MQW may emit first light having a central wavelength range of about 450 nm to about 495 nm, that is, light in the blue wavelength band.

The active layer MQW may include a material having a single or multi-quantum well structure. When the active layer MQW includes a material having a multi-quantum well structure, it may have a structure in which a plurality of well layers and barrier layers are alternately stacked. In this case, the well layer may be formed of InGaN, and the barrier layer may be formed of GaN or AlGaN but is not limited thereto. The thickness of the well layer may be about 1 nm to about 4 nm, and the thickness of the barrier layer may be about 3 nm to about 10 nm.

Alternatively, the active layer MQW may have a structure in which semiconductor materials having a high band gap energy and semiconductor materials having a low band gap energy are alternately stacked with each other, may include other Group III to V semiconductor materials according to the wavelength range of emitted light. The light emitted from the active layer MQW is not limited to the first light (light in the blue wavelength band), and may emit second light (light in the green wavelength band) or third light (light in the red wavelength band) in some cases. The thickness of the active layer MQW may be about 10 nm to about 25 nm.

The first semiconductor layer SEM1 may be doped with a first conductive dopant, such as Mg, Zn, Ca, Se, or Ba. For example, the first semiconductor layer SEM1 may be p-GaN doped with p-type Mg. The thickness of the first semiconductor layer SEM1 may be about 30 nm to about 200 nm.

In one or more other embodiments, a superlattice layer may be further included between the active layer MQW and the second semiconductor layer SEM2. The superlattice layer may be a layer for relieving stress between the second semiconductor layer SEM2 and the active layer MQW. The superlattice layer may be formed of InGaN or GaN. In addition, an electron-blocking layer may be further included between the first semiconductor layer SEM1 and the active layer MQW. The electron-blocking layer may be a layer to reduce or prevent the likelihood of too many electrons flowing into the active layer MQW. For example, the electron-blocking layer may be p-AlGaN doped with p-type Mg. The thickness of the electron-blocking layer may be about 10 nm to about 50 nm. The electronic-blocking layer may be omitted.

The transparent conductive layer TCO may be located on the lower surface of the first semiconductor layer SEM1. The transparent conductive layer TCO may directly contact the first semiconductor layer SEM1. The transparent conductive layer TCO may be formed transparently to emit light. The transparent conductive layer TCO may be formed of a transparent conductive oxide, such as indium tin oxide (ITO) and indium zinc oxide (IZO). The transparent conductive layer TCO may be omitted.

An element-insulating layer INSO may wrap the sides of the third semiconductor layer SEM3, the second semiconductor layer SEM2, the active layer MQW, the first semiconductor layer SEM1, and the transparent conductive oxide TCO and the top surface of the transparent conductive oxide TCO. The element-insulating layer INSO has, or defines, two openings. For example, the element-insulating layer INSO includes a first opening OP-L1 and a second opening OP-L2. The element-insulating layer INSO may include a silicon compound, metal oxide, or the like. For example, the element-insulating layer INSO may include silicon oxide, silicon nitride, silicon oxynitride, aluminum oxide, tantalum oxide, hafnium oxide, zirconium oxide, titanium oxide, and/or the like.

The first contact electrode CTE1 and the second contact electrode CTE2 are respectively located on the two openings. For example, the first contact electrode CTE1 may be located on the first opening OP-L1 and may contact the first semiconductor layer SEM1. The second contact electrode CTE2 may be located on the second opening OP-L2 and may contact the second semiconductor layer SEM2. To this end, the second opening OP-L2 may expose the second semiconductor layer SEM2. The second opening OP-L2 may have a wider diameter than the first opening OP-L1.

The element-insulating layer INSO may cover side surfaces of the recess defined by, or to define, the second opening OP-L2.

Because the first contact electrode CTE1 and the second contact electrode CTE2 are located on the top surface of the light-emitting element LE, they may be transparent electrodes. For example, the first contact electrode CTE1 and the second contact electrode CTE2 may be formed of a transparent conductive oxide, such as indium tin oxide (ITO) and indium zinc oxide (IZO).

Referring to FIG. 7, the via layer VIA may support the lead lines LDL connecting the first contact electrode CTE1 and the second contact electrode CTE2 with the first reflective electrode SCT1 and the second reflective electrode SCT2, and to flatten the step formed by the light-emitting element LE. The via layer VIA may include an organic insulating material. For example, the via layer VIA may include acrylic-based resin, epoxy-based resin, imide-based resin, ester-based resin, or the like. The lead line LDL may include a first lead line LDL1 and a second lead line LDL2. The via layer VIA may be formed to be higher than the height of the light-emitting element LE but is not limited thereto.

Referring to FIG. 7, the via layer VIA may include, or define, a plurality of contact holes. For example, the via layer VIA may include a first contact hole CH1 for connecting the first contact electrode CTE1 and the first lead line LDL1, a second contact hole CH2 for connecting the first lead line LDL1 to the first reflective electrode SCT1, a third contact hole CH3 for connecting the second contact electrode CTE2 to the second lead line LDL2, and a fourth contact hole CH4 for connecting the second lead line LDL2 to the second reflective electrode SCT2.

Referring to FIG. 6, the wavelength controller 200 may be located on the light-emitting element portion LEP.

The wavelength controller 200 may include a partition wall PW and a wavelength conversion layer QDL.

The partition wall PW is arranged to extend in the first direction DR1 and in the second direction DR2, and may be formed in a grid-like pattern throughout the display area DA. Furthermore, the partition wall PW may not overlap with the plurality of light-emitting areas EA1, EA2, and EA3, and may overlap with the non-emitting area NEA.

The partition wall PW may serve to provide space for the wavelength conversion layer QDL to be formed. The partition wall PW may have a relatively large thickness to provide a space for the wavelength conversion layer QDL to be formed. For example, the partition wall PW may include an organic insulating material so that the partition wall PW may be made thick. The organic insulating material may include, for example, epoxy-based resin, acrylic-based resin, cardo-based resin, imide-based resin, or the like.

In one or more embodiments, the partition wall PW may block the transmission of light in the non-emitting area NEA. The partition wall PW may further include a light-blocking material, and may include a dye or pigment having light-blocking properties. For example, the partition wall PW may be a black matrix. External light incident from the outside of the display device 10 may cause a problem of distorting the color gamut of the wavelength controller 200. The partition wall PW including a light-blocking material is located in the wavelength controller 200 so that at least a portion of external light is absorbed by the light-blocking material. Therefore, color distortion caused by external light reflection may be reduced. Furthermore, the partition wall PW containing a light-blocking material may reduce or prevent light from intruding between adjacent light-emitting areas and causing color mixing, thereby further improving the color reproduction rate.

The wavelength conversion layer QDL may convert or shift the peak wavelength of incident light into light of another corresponding peak wavelength, and may emit the light. The wavelength conversion layer QDL may convert the blue first light emitted from the light-emitting element LE into red second light or green third light, or may transmit the blue first light as it is.

The wavelength conversion layer QDL may be located in each light-emitting area EA1, EA2, and EA3 compartmentalized by the partition wall PW, and may be spaced apart from each other. That is, the wavelength conversion layer QDL may be formed in an island pattern spaced apart from each other. The wavelength conversion layer QDL may overlap the first light-emitting area EA1, the second light-emitting area EA2, and the third light-emitting area EA3, respectively. In one or more embodiments, the wavelength conversion layers QDL may respectively, completely overlap the first light-emitting area EA1, the second light-emitting area EA2, and the third light-emitting area EA3.

The wavelength conversion layer QDL includes a first wavelength conversion pattern WCL1 overlapping with the first light-emitting area EA1, a second wavelength conversion pattern WCL2 overlapping with the second light-emitting area EA2, and a light transmission pattern TPL overlapping the third light-emitting area EA3.

The first wavelength conversion pattern WCL1 may overlap the first light-emitting area EA1. The first wavelength conversion pattern WCL1 may convert or shift the peak wavelength of incident light into light of another corresponding peak wavelength, and may emit the light. In one or more embodiments, the first wavelength conversion pattern WCL1 may convert and emit blue first light emitted from the light-emitting element LE of the first light-emitting area EA1 into second light, which is red light having a single peak wavelength in the range of about 610 nm to about 650 nm.

The first wavelength conversion pattern WCL1 may include a first base resin BRS1, a first wavelength conversion particle WCP1, and a scatterer SCP. The first base resin BRS1 may include a light-transmitting organic material. For example, the first base resin BRS1 may include epoxy-based resin, acrylic-based resin, cardo-based resin, or imide-based resin.

The first wavelength conversion particle WCP1 may convert the first light incident from the light-emitting element LE into the second light. For example, the first wavelength conversion particle WCP1 may convert light in the blue wavelength band into light in the red wavelength band. The first wavelength conversion particle WCP1 may be a quantum dot (QD), a quantum rod, a fluorescent material, or a phosphorescent material. For example, quantum dots may be particulate materials that emit a corresponding color as electrons transition from the conduction band to the valence band.

The quantum dots may be semiconductor nanocrystalline materials. Depending on its composition and size, the quantum dot may have a corresponding bandgap to absorb light, and may emit light with a unique wavelength. Examples of the semiconductor nanocrystals of the quantum dots include Group IV nanocrystals, Group II-VI compound nanocrystals, Group III-V compound nanocrystals, Group IV-VI nanocrystals, or combinations thereof.

The Group II-VI compound is a binary compound selected from the group consisting of CdSe, CdTe, ZnS, ZnSe, ZnTe, ZnO, HgS, HgSe, HgTe, MgSe, MgS, or mixtures thereof; ternary compounds selected from the group consisting of InZnP, AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, or mixtures thereof; and/or a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, or mixtures thereof.

The Group III-V compound is a binary compound selected from the group consisting of GaN, GaP, GaAs, GaSb, AlN, AlP, AlAs, AlSb, InN, InP, InAs, InSb, or mixtures thereof; a ternary compound selected from the group consisting of GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or mixtures thereof; and/or a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or mixtures thereof.

The Group IV-VI compounds may be selected from the group consisting of binary compounds selected from the group consisting of SnS, SnSe, SnTe, PbS, PbSe, PbTe, or mixtures thereof; ternary compounds selected from the group consisting of SnSeS, SnSeTe, SnSTe, PbSeS, PbSeTe, PbSTe, SnPbS, SnPbSe, SnPbTe, or mixtures thereof; and/or a quaternary compound selected from the group consisting of SnPbSSe, SnPbSeTe, SnPbSTe, or mixtures thereof. The Group IV element may be selected from the group consisting of Si, Ge, or mixtures thereof. The Group IV compound may be a binary compound selected from the group consisting of SiC, SiGe, or mixtures thereof.

The binary, ternary, or quaternary compounds may be present in the particle at a uniform concentration or may be present in the same particle with a partially different concentration distribution. The quantum dot may also have a core/shell structure in which one quantum dot surrounds another. The interface of the core and shell may have a concentration gradient where the concentration of an element present in the shell decreases toward the center.

In one or more embodiments, the quantum dot may have a core-shell structure including a core including a nanocrystal as described above and a shell surrounding the core. The shell of the quantum dot may act as a protective layer to reduce or prevent chemical denaturation of the core to maintain semiconductor properties and/or as a charging layer to impart electrophoretic properties to the quantum dot. The shell may be monolayer or multilayer. Examples of shells for the quantum dots include oxides of metals or non-metals, semiconductor compounds, or combinations thereof.

For example, the oxides of said metals or non-metals may be exemplified by binary compounds, such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds, such as MgAl₂O₄, CoFe₂O₄, NiFe₂O₄, CoMn₂O₄, but the present disclosure is not limited thereto.

In addition, the semiconductor compounds may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. but are not limited thereto.

The second wavelength conversion pattern WCL2 may overlap the second light-emitting area EA2. The second wavelength conversion pattern WCL2 may emit light by converting or shifting the peak wavelength of incident light into light of another corresponding peak wavelength. In one or more embodiments, the second wavelength conversion pattern WCL2 converts the blue first light emitted from the light-emitting element LE of the second light-emitting area EA2 into green third light having a peak wavelength in the range of about 510 nm to about 550 nm, and may emit green third light.

The second wavelength conversion pattern WCL2 may include a second base resin BRS2, and may include a second wavelength conversion particle WCP2 and the scatterer SCP dispersed in the second base resin BRS2.

The second base resin BRS2 may be made of a material with high light transmittance, may be made of the same material as the first base resin BRS1, or may include at least one of the materials exemplified as their constituent materials.

The second wavelength conversion particle WCP2 may convert or shift the peak wavelength of incident light to another corresponding peak wavelength. In one or more embodiments, the second wavelength conversion particle WCP2 may convert the blue first light provided from the light-emitting element LE into green third light having a peak wavelength in the range of about 510 nm to about 550 nm, and may emit the green third light. Examples of the second wavelength conversion particle WCP2 include quantum dots, quantum rods, or phosphors. A more thorough description of the second wavelength conversion particle WCP2 is substantially the same as, or similar to, that described above in the description of the first wavelength conversion particle WCP1 and will be omitted.

The light transmission pattern TPL may be arranged to overlap the third light-emitting area EA3. The light transmission pattern TPL may transmit incident light. The light transmission pattern TPL may directly transmit the blue first light emitted from the light-emitting element LE located in the third light-emitting area EA3. The light transmission pattern TPL may include a third base resin BRS3 and the scatterer SCP dispersed in the third base resin BRS3. Because the third base resin BRS3 is substantially the same as, or similar to, the above-described first base resin BRS1, description thereof will be omitted.

The wavelength controller 200 may further include a capping layer CAP. The capping layer CAP may be located on the wavelength conversion layer QDL and the partition wall PW. The capping layer CAP may include an inorganic material. For example, the capping layer CAP may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxide. Meanwhile, the drawing illustrates that the capping layer CAP is formed as a single layer, but the present disclosure is not limited thereto. For example, the capping layer CAP may be formed of multiple layers in which inorganic layers containing at least one of the materials that the capping layer CAP may include are alternately stacked. The thickness of the capping layer CAP may range from about 0.05 μm to about 2 μm, but is not limited thereto.

Meanwhile, the color filter layer CFL may be located on the wavelength controller 200. The color filter layer CFL may include a first overcoat layer OC1, a first color filter CF1, a second color filter CF2, a third color filter CF3, and a second overcoat layer OC2.

The first overcoat layer OC1 may be located on the wavelength controller 200. The first overcoat layer OC1 may be directly located on the third capping layer CAP3 of the wavelength controller 200. The first overcoat layer OC1 may be located entirely over the display area DA, and may have a flat surface. The first overcoat layer OC1 may flatten the step formed by the lower wavelength controller 200 to facilitate the formation of the color filter layer CFL.

The first overcoat layer OC1 may include a light-transmitting organic material. For example, the first overcoat layer OC1 may include epoxy resin, acrylic resin, cardo resin, or imide resin.

The first color filter CF1, the second color filter CF2, and the third color filter CF3 may be located on the first overcoat layer OC1. The first color filter CF1 may be located in the first emitting area EA1, the second color filter CF2 may be located in the second emitting area EA2, and the third color filter CF3 may be located in the third emitting area EA3.

The first color filter CF1, the second color filter CF2, and the third color filter CF3 may include a colorant, such as the dye or pigment that absorbs wavelengths other than the corresponding color wavelength. The first color filter CF1 may selectively transmit the second light (e.g., red light), and may block or absorb the first light (e.g., blue light) and the third light (e.g., green light). The second color filter CF2 may selectively transmit the third light (e.g., green light), and may block or absorb the first light (e.g., blue light) and the second light (e.g., red light). The third color filter CF3 may selectively transmit the first light (e.g., blue light), and may block or absorb the second light (e.g., red light) and the third light (e.g., green light). For example, the first color filter CF1 may be a red color filter, the second color filter CF2 may be a green color filter, and the third color filter CF3 may be a blue color filter.

In one or more embodiments, the light incident on the first color filter CF1 may be light converted to second light in the first wavelength conversion pattern WCL1, the light incident on the second color filter CF2 may be light converted to third light in the second wavelength conversion pattern WCL2, and the light incident on the third color filter CF3 may be first light transmitted through the light transmission pattern TPL. As a result, the second light transmitted through the first color filter CF1, the third light transmitted through the second color filter CF2, and the first light transmitted through the third color filter CF3 may be emitted to the top of the substrate SUB to achieve full color.

The first color filter CF1, the second color filter CF2, and the third color filter CF3 may absorb a portion of the light entering from the outside of the display device 10 to reduce the reflected light caused by external light. Accordingly, the first color filter CF1, the second color filter CF2, and the third color filter CF3 may reduce or prevent color distortion due to reflection of external light.

The planar area of each of the first color filter CF1, the second color filter CF2, and the third color filter CF3 may be larger than the planar area of each of the plurality of light-emitting areas EA1, EA2, and EA3 (e.g., respectively). For example, the first color filter CF1 may be larger than the planar area of the first emitting area EA1. The second color filter CF2 may be larger than the planar area of the second emitting area EA2. The third color filter CF3 may be larger than the planar area of the third emitting area EA3. However, it is not limited thereto, and the planar area of each of the first color filter CF1, the second color filter CF2, and the third color filter CF3 may be equal to the planar area of each of the plurality of light-emitting areas EA1, EA2, and EA3 (e.g., respectively).

The second overcoat layer OC2 may be located on the color filter layer CFL. The second overcoat layer OC2 may be directly located on the color filter layer CFL. The second overcoat layer OC2 may be located entirely in the display area DPA, and may have a flat surface. The second overcoat layer OC2 may flatten the step formed by the color filter layer CFL therebelow. The second overcoat layer OC2 may include a light-transmitting organic material, and may be substantially the same as, or similar to, the first overcoat layer OC1 described above.

The display device 10 according to one or more embodiments may reduce or prevent the likelihood of the first reflective electrode SCT1 and the second reflective electrode SCT2 being connected by forming the inter-electrode planarization layer PFL between the first pad electrode APD and the second pad electrode CPD.

Additionally, by forming an inter-electrode flattening/planarization layer (PFL) containing a light-blocking material between the first pad electrode (APD) and the second pad electrode (CPD), it is possible to block light from traveling to the light-emitting device (LE).

Further, the progression of light to the light-emitting element LE may be blocked by forming an inter-electrode planarization layer PFL including a light-blocking material between the first pad electrode APD and the second pad electrode CPD.

In addition, there may be resolved a residual issue that may occur between the pad electrodes during wet etching to secure a separation distance between the first reflective electrode SCT1 and the second reflective electrode SCT2. In addition, the first pad electrode APD and the second pad electrode CPD are less likely to be exposed to the etch solution, so there is no risk of Ag residue. Furthermore, there is a degree of freedom in the selection of the etchant. For reference, if the first pad electrode APD and the second pad electrode CPD contain aluminum, there may be a problem that if the aluminum is exposed to the etchant, it may cause Ag residue on the surface due to galvanic phenomena.

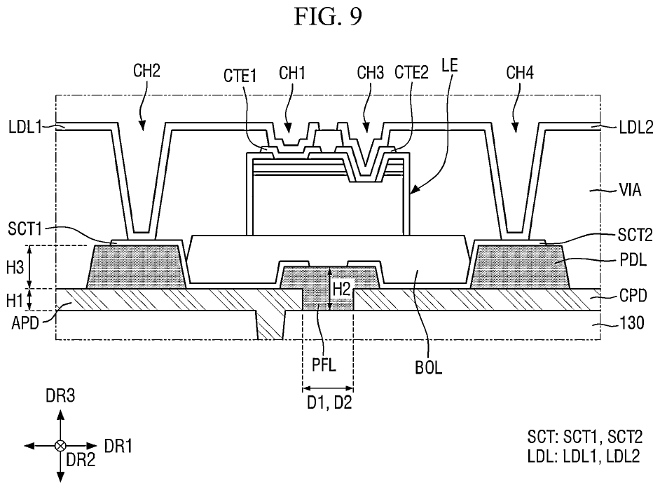

FIG. 9 is an enlarged view schematically illustrating the first light-emitting area described with reference to FIG. 6 according to one or more other embodiments.

Referring to FIG. 9, one or more embodiments may differ from the one or more embodiments corresponding to FIG. 8 in that the inter-electrode planarization layer PFL protrudes above the top surfaces of the first pad electrode APD and the second pad electrode CPD. Hereinafter, descriptions overlapping with the above will be omitted and differences will be described.

The first pad electrode APD and the second pad electrode CPD are arranged to be spaced apart from each other. The first pad electrode APD and the second pad electrode CPD may be arranged to be spaced apart by the first separation distance D1. The first separation distance D1 may be about 4 μm to about 6 μm. The height H1 of the first pad electrode APD and the second pad electrode CPD may be about 6000 Å to about 7000 Å.

The inter-electrode planarization layer PFL may be located between the first pad electrode APD and the second pad electrode CPD. The inter-electrode planarization layer PFL may fill the space between the first pad electrode APD and the second pad electrode CPD. A lower width D2 of the inter-electrode planarization layer PFL (e.g., a width of a lower portion of the inter-electrode planarization layer PFL) may be equal to the first separation distance D1 between the first pad electrode APD and the second pad electrode CPD. The height (e.g., thickness) H2 of the inter-electrode planarization layer PFL may be higher than the height (thickness) H1 of the first pad electrode APD and the second pad electrode CPD. The height H2 of the inter-electrode planarization layer PFL may be about 12,000 Å to about 14,000 Å. Meanwhile, the height H2 of the inter-electrode planarization layer PFL may be equal to the height (e.g., thickness) H3 of the bank PDL. Accordingly, the height H3 of the bank PDL may be about 12000 Å to about 14000 Å.

The inter-electrode planarization layer PFL may cover at least a portion of the first pad electrode APD and at least a portion of the second pad electrode CPD. The first reflective electrode SCT1 may cover a portion of the inter-electrode planarization layer PFL, a portion of the first pad electrode APD, and a portion of the bank PDL. The second reflective electrode SCT2 may cover a portion of the inter-electrode planarization layer PFL, a portion of the second pad electrode CPD, and a portion of the bank PDL. The first reflective electrode SCT1 and the second reflective electrode SCT2 are arranged to be spaced apart from each other on the inter-electrode planarization layer PFL.

An organic pattern layer BOL may be located on the reflective electrode SCT and on the inter-electrode planarization layer PFL located in the opening of the bank PDL.

Compared to the inter-electrode planarization layer PFL of FIG. 7, the inter-electrode planarization layer PFL of FIG. 9 is formed higher (e.g., thicker) than the height H1 of the first pad electrode APD and the second pad electrode CPD, so that the inter-electrode planarization layer PFL may protrude above the first pad electrode APD and the second pad electrode CPD. In this way, when the inter-electrode planarization layer PFL protrudes above the first pad electrode APD and the second pad electrode CPD, the contact surface with the organic pattern layer BOL is widened, and the adhesion between the organic pattern layer BOL and the underlying layer may be improved.

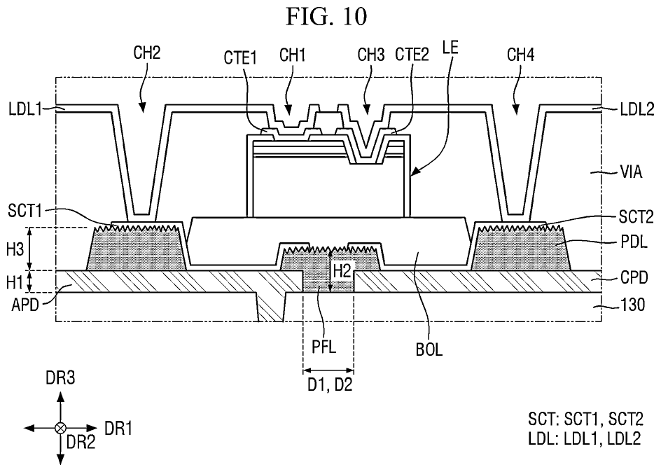

FIG. 10 is an enlarged view schematically illustrating the first light-emitting area described with reference to FIG. 6 according to one or more other embodiments.

Referring to FIG. 10, it differs from the one or more embodiments corresponding to FIG. 9 in that the roughness of the top surface of the inter-electrode planarization layer PFL and the bank PDL is improved to make the contact surface with the organic pattern layer BOL wider. Hereinafter, descriptions overlapping with the above will be omitted and differences will be described.

After the inter-electrode planarization layer PFL and bank PDL are formed as shown in FIG. 9, a descum or ashing process may be added. These processes may increase the surface roughness of the top surface of the PFL and PDL, resulting in a larger contact area with the organic pattern layer BOL. The inter-electrode planarization layer PFL and the bank PDL may have a roughness of the top surface that is greater than that of the bottom surface.

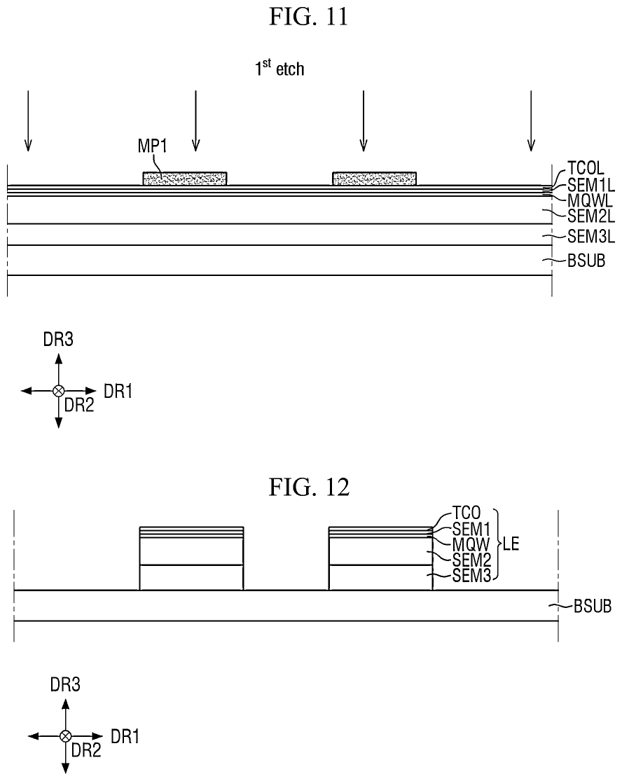

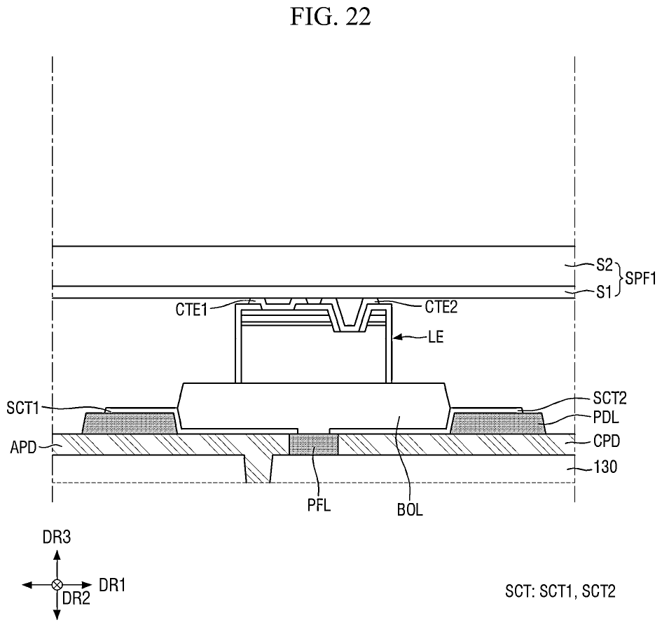

FIGS. 11 to 26 are diagrams to illustrate a method of manufacturing a display device according to one or more embodiments.

FIGS. 11 to 26 each illustrate a cross-sectional view of the structure of each layer of the display device 10 in the order of formation. FIGS. 11 to 26 mainly illustrate the manufacturing process of the light-emitting element portion LEP, which may be roughly corresponding to the cross-sectional view of FIG. 7. Furthermore, the following will focus on the first light-emitting area EA1 of the display device 10.

First, referring to FIGS. 11 to 16, a plurality of light-emitting elements LE are formed on a base substrate BSUB.

For example, the base substrate BSUB is prepared. The base substrate BSUB may be a sapphire Al₂O₃ substrate or a silicon wafer including silicon. However, it is not limited thereto, and in one or more embodiments, a case where the base substrate BSUB is a sapphire substrate will be described as an example.

A plurality of semiconductor material layers SEM3L, SEM2L, MQWL, and SEM1L are formed on the base substrate BSUB. The plurality of semiconductor material layers grown by the epitaxial method may be formed by growing a seed crystal. Methods for forming semiconductor material layers include electron beam deposition, physical vapor deposition (PVD), chemical vapor deposition (CVD), plasma laser deposition (PLD), dual-type thermal evaporation, sputtering, metal organic chemical vapor deposition (MOCVD), and/or the like, and preferably formed by metal organic chemical vapor deposition (MOCVD). However, it is not limited thereto.

A precursor material(s) for forming the plurality of semiconductor material layers is not particularly limited within the range that may be conventionally selected for forming the subject material. In one example, the precursor material may be a metal precursor including an alkyl group, such as a methyl or ethyl group. For example, it may be a compound, such as trimethyl gallium (Ga(CH₃)₃), trimethyl aluminum (Al(CH₃)₃), triethyl phosphate ((C₂H₅)₃PO₄) but are not limited thereto.

For example, a third semiconductor material layer SEM3L is formed on the base substrate BSUB. While the drawings illustrate the third semiconductor material layer SEM3L being further stacked, it is not limited to this, and a plurality of layers may be formed. The third semiconductor material layer SEM3L may reduce a lattice constant difference between a second semiconductor material layer SEM2L and the base substrate BSUB. For example, the third semiconductor material layer SEM3L may include an undoped semiconductor, which may be an n-type or p-type undoped material. In one or more embodiments, the third semiconductor material layer SEM3L may be at least one of undoped InAlGaN, GaN, AlGaN, InGaN, AlN, or InN but is not limited thereto.

The second semiconductor material layer SEM2L, the active material layer MQWL, and the first semiconductor material layer SEM1L are sequentially formed on the third semiconductor material layer SEM3L by using the above-described method.

Then, a transparent conductive material layer TCOL is formed on the plurality of semiconductor material layers SEM3L, SEM2L, MQWL, and SEM1L. The transparent conductive material layer TCOL may cover all of the plurality of semiconductor material layers SEM3L, SEM2L, MQWL, and SEM1L. The transparent conductive material layer TCOL may be formed of a transparent conductive oxide, such as indium tin oxide (ITO) and indium zinc oxide (IZO).

Next, a plurality of semiconductor material layers SEM3L, SEM2L, MQWL, SEM1L and a transparent conductive material layer TCOL are etched.

For example, a plurality of first mask patterns MP1 are formed on the transparent conductive material layer TCOL. The first mask pattern MP1 may be a hard mask containing an inorganic material or a photoresist mask containing an organic material. The first mask pattern MP1 reduces or prevents etching of the lower plurality of semiconductor material layers SEM3L, SEM2L, MQWL, and SEM1L and the transparent conductive material layer TCOL. Then, a portion of the plurality of semiconductor material layers SEM3L, SEM2L, MQWL, and SEM1L and the transparent conductive material layer TCOL is etched (1st etch) using the plurality of first mask patterns MP1 as a mask.

As shown in FIG. 12, on the base substrate BSUB, a plurality of semiconductor material layers SEM3L, SEM2L, MQWL, and SEM1L and a transparent conductive material layer TCOL non-overlapping with the first mask pattern MP1 may be etched and removed, and the non-etched portion overlapping with the first mask pattern MP1 may be formed into a plurality of light-emitting elements LE.

The plurality of semiconductor material layers SEM3L, SEM2L, MQWL, and SEM1L and reflective material layers may be etched by conventional methods. For example, the process of etching the plurality of semiconductor material layers SEM3L, SEM2L, MQWL, and SEM1L and transparent conductive material layers TCOL may be performed by a dry etching method, a wet etching method, a reactive ion etching (RIE) method, a deep reactive ion etching (DRIE) method, an inductively coupled plasma reactive ion etching (ICP-RIE) method. In the case of dry etching methods, anisotropic etching is possible, which may be suitable for vertical etching. When using the etching method described above, the etching etchant may be Cl₂ or O₂. However, it is not limited thereto.

The plurality of semiconductor material layers SEM3L, SEM2L, MQWL, and SEM1L and the transparent conductive material layer TCOL overlapping the first mask pattern MP1 are formed in the plurality of light-emitting elements LE without being etched. Thus, the plurality of light-emitting elements LE are formed including the third semiconductor layer SEM3, the second semiconductor layer SEM2, the active layer MQW, the first semiconductor layer SEM1, and the transparent conductive material layer TCO.

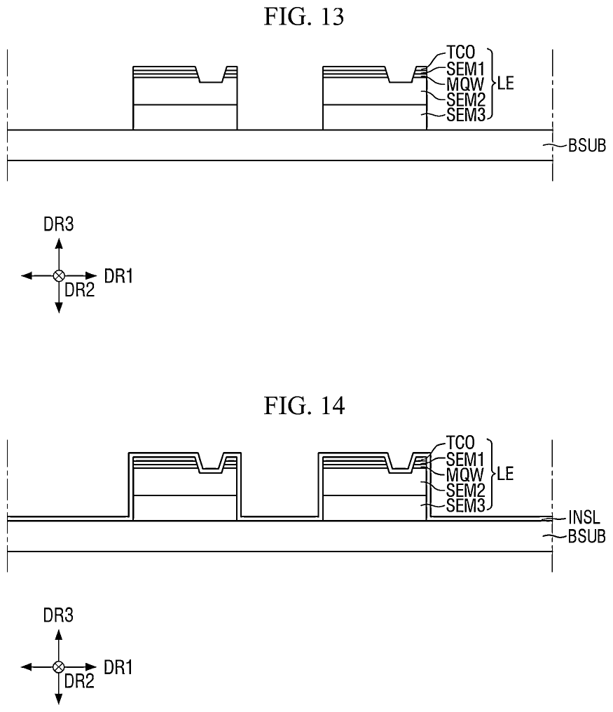

Next, referring to FIG. 13, an opening exposing the second semiconductor layer SEM2 is formed on the transparent conductive material layer TCO by an etching process. The etching process may be the dry etching method, the wet etching method, the reactive ion etching (RIE) method, the deep reactive ion etching (DRIE) method, the inductively coupled plasma reactive ion etching (ICP-RIE) method, or the like, as described above.

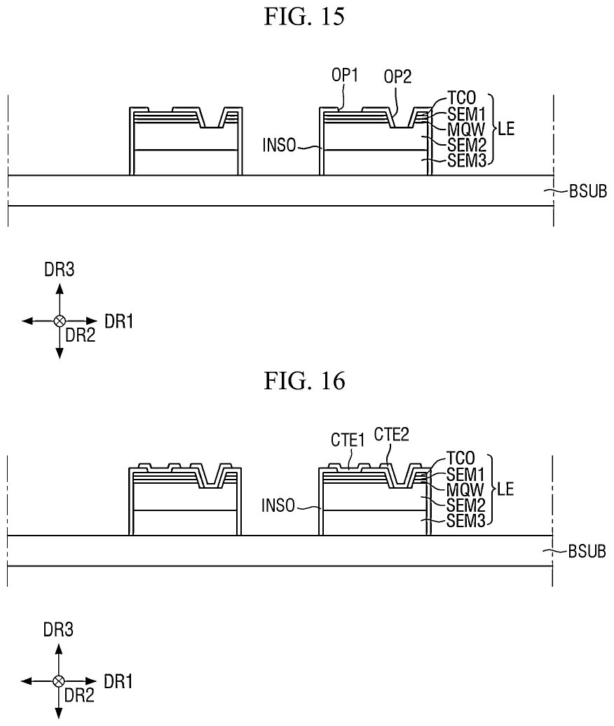

Referring to FIGS. 14 and 15, an insulating material layer INSL, which has/defines a plurality of openings OP1 and OP2, may be formed on the base substrate BSUB on which the light-emitting element LE is formed.

For example, the insulating material layer INSL may be formed on the outer surface of the plurality of light-emitting elements LE. The insulating material layer INSL may be formed on the entire surface of the base substrate BSUB so that it is formed not only on the light-emitting elements LE but also on the top surface of the base substrate BSUB exposed by the light-emitting elements LE.

Next, a second etch may be performed to partially remove the insulating material layer INSL to form the light-emitting element LE including the element-insulating layer INSO.

For example, the second etch process may be performed in which the insulating material layer INSL is partially removed such that the insulating material layer INSL exposes the top surface of the light-emitting element LE but encloses the sides of the light-emitting element LE. For example, in this process, the insulating material layer INSL may define the first opening OP1 by removing at least a portion of the top surface of the transparent conductive layer TCO of the light-emitting element LE. Further, the insulating material layer INSL may define the second opening OP2 by removing at least a portion of the second semiconductor layer SEM2 of the light-emitting element LE. The process of partially removing the insulating material layer INSL may be performed by an etching process using a mask.

Next, referring to FIG. 16, the light-emitting element LE may be formed by forming a first contact electrode CTE1 and a second contact electrode CTE2 on the light-emitting element LE.

For example, the first contact electrode CTE1 and the second contact electrode CTE2 are formed by stacking a contact electrode material layer on the base substrate BSUB. Then, the contact electrode material layer is etched by the etching process to form the first contact electrode CTE1 covering the first opening OP1 of the light-emitting element LE, and to form the second contact electrode CTE2 covering the second opening OP2. The contact electrode material layer may be formed of a transparent conductive material. For example, the contact electrode material layer may be a transparent conductive oxide, such as indium tin oxide (ITO) and indium zinc oxide (IZO). The first contact electrode CTE1 may be electrically connected to the first semiconductor layer SEM1 through the first opening OP1, and the second contact electrode CTE2 may be electrically connected to the second semiconductor layer SEM2 through the second opening OP2.

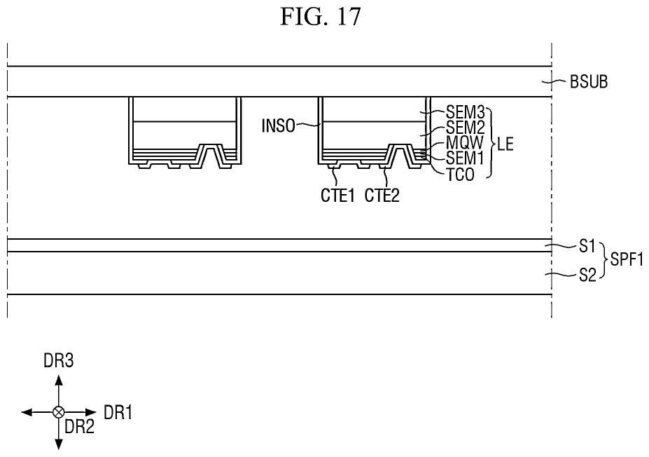

Next, referring to FIG. 17, a support film SPF1 is attached to the plurality of light-emitting elements LE of the base substrate BSUB manufactured in FIG. 16.

For example, the support film SPF1 is attached on the plurality of light-emitting elements LE. The support film SPF1 may be aligned on the plurality of light-emitting elements LE and may be attached to the first contact electrode CTE1 and the second contact electrode CTE2 of the plurality of light-emitting elements LE. The plurality of light-emitting elements LE may be arranged in large numbers, and may be attached to the support film SPF1 without being detached.

The support film SPF1 may be composed of a support layer S2, and an adhesive layer S1 located on the support layer S2. The support layer S2 may be made of a transparent, mechanically stable material that allows light to pass through. For example, the support layer S2 may include a transparent polymer, such as polyester, polyacrylic, polyepoxy, polyethylene, polystyrene, polyethylene terephthalate, or the like. The adhesive layer S1 may include an adhesive material for bonding the light-emitting element LE. For example, the adhesive material may include urethane acrylate, epoxy acrylate, polyester acrylate, and/or the like. The adhesive material may be a material whose adhesive strength changes as ultraviolet (UV) or heat is applied, and thus the adhesive layer S1 may be suitably separated from the light-emitting element LE.

Next, the base substrate BSUB is irradiated with a first laser (1^{st} laser) to separate the light-emitting elements LE from the base substrate BSUB. The base substrate BSUB is separated from each third semiconductor layer SEM3 of the plurality of light-emitting elements LE.

The process of separating the base substrate BSUB may be separated by a laser lift-off (LLO) process. The laser lift-off process uses a laser. A KrF excimer laser (about 248 nm wavelength) may be used as the source. The energy density of the excimer laser may be irradiated in the range of about 550 mJ/cm² to about 950 mJ/cm², and the incident area may be in the range of about 50×50 μm² to about 1×1 cm² but is not limited thereto. By irradiating the base substrate BSUB with the laser, the base substrate BSUB may be separated from the light-emitting element LE.

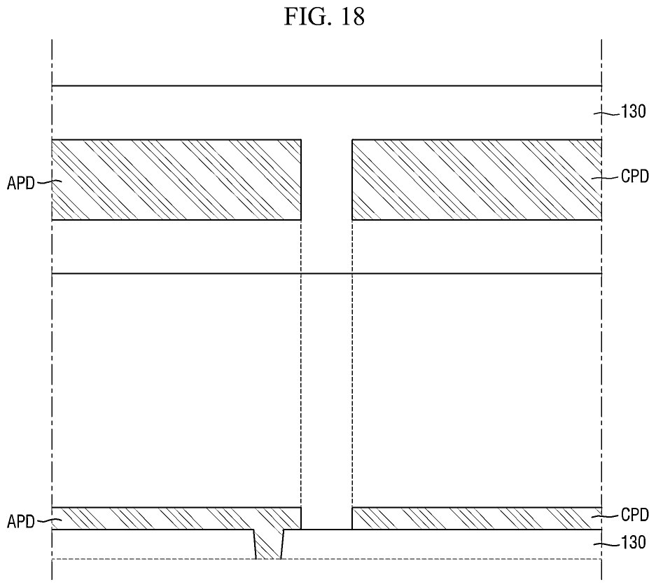

Meanwhile, FIGS. 18 to 21 and FIG. 23 illustrate a plan view corresponding to the cross-sectional view for convenience of explanation.

First, referring to FIG. 18, a substrate 110 is prepared. As described with reference to FIG. 6, the substrate 110 may be formed of a second planarization layer 130, a first pad electrode APD, and a second pad electrode CPD. The first pad electrode APD and the second pad electrode CPD may be arranged to be spaced apart from each other.

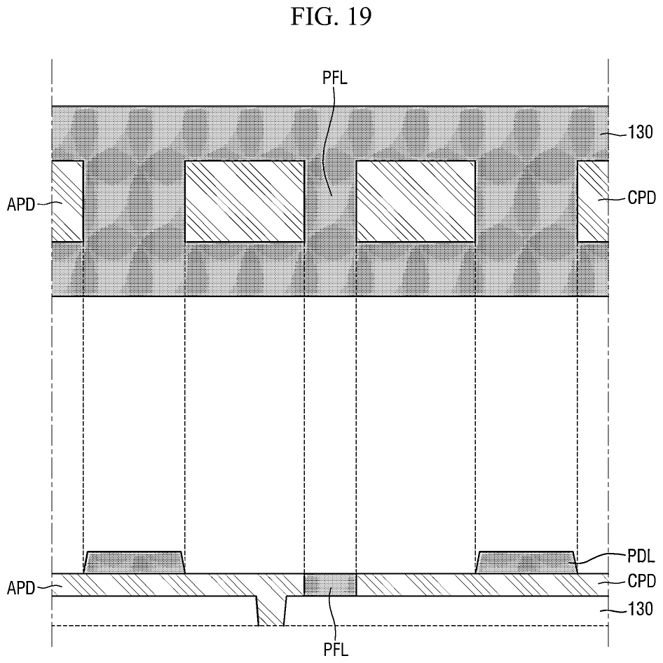

Thereafter, referring to FIG. 19, a bank PDL and an inter-electrode planarization layer PFL may be formed on the second planarization layer 130. For example, an organic material layer including a light-blocking material is applied to the entire substrate on which the first pad electrode APD and the second pad electrode CPD are formed. The organic material layer may have the same thickness as the first pad electrode APD and the second pad electrode CPD. For example, the organic material layer may be applied to a thickness of about 6000 Å to about 7000 Å, but is not limited thereto. In another variant, the organic material layer may be applied to a thickness of about 12,000 Å to about 14,000 Å. Then, the organic material layer may be etched using a masked etch process to form the bank PDL and the inter-electrode planarization layer PFL. The bank PDL may expose at least a portion of the first pad electrode APD and at least a portion of the second pad electrode CPD. The bank PDL and the inter-electrode planarization layer PFL may be connected to each other.

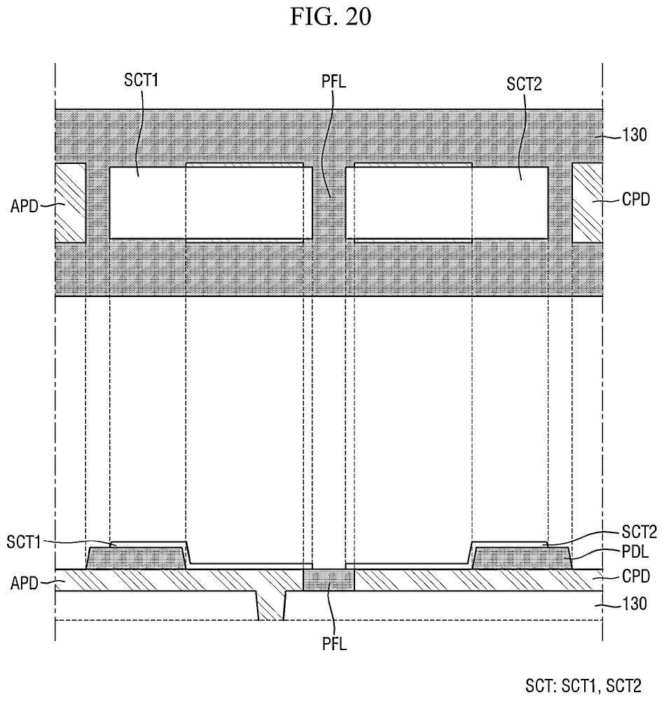

Then, referring to FIG. 20, a first reflective electrode SCT1 and a second reflective electrode SCT2 are formed on the bank PDL, the first pad electrode APD, and the second pad electrode CPD. For example, a reflective electrode material layer may cover the bank PDL, the first pad electrode APD, the inter-electrode planarization layer PFL, and the second pad electrode CPD. Thereafter, a photoresist pattern is formed to cover at least a portion of the reflective electrode material layer. The photoresist pattern may be applied to a thickness of about 6000 Å to about 7000 Å, but is not limited thereto. Then, wet etching may be performed using an etching chemical solution. The reflective electrode material layer in the area where the photoresist pattern is not located is removed to form a first reflective electrode SCT1 and a second reflective electrode SCT2 spaced apart from each other.

Meanwhile, when the reflective electrode material layer is applied without forming the inter-electrode planarization layer PFL on the second planarization layer 130 and wet etching is performed by the etching solution, the reflective electrode material layer located in the crevice between the first pad electrode APD and the second pad electrode CPD may not be cleanly etched. Accordingly, there may be a possibility that a short circuit may occur between the first pad electrode APD and the second pad electrode CPD.

On the other hand, when forming the inter-electrode planarization layer PFL between the first pad electrode APD and the second pad electrode CPD, as in one or more embodiments, the reflective electrode material layer may be etched cleanly between the first pad electrode APD and the second pad electrode CPD. Accordingly, it is possible to reduce or prevent the likelihood of a short circuit between the first pad electrode APD and the second pad electrode CPD.

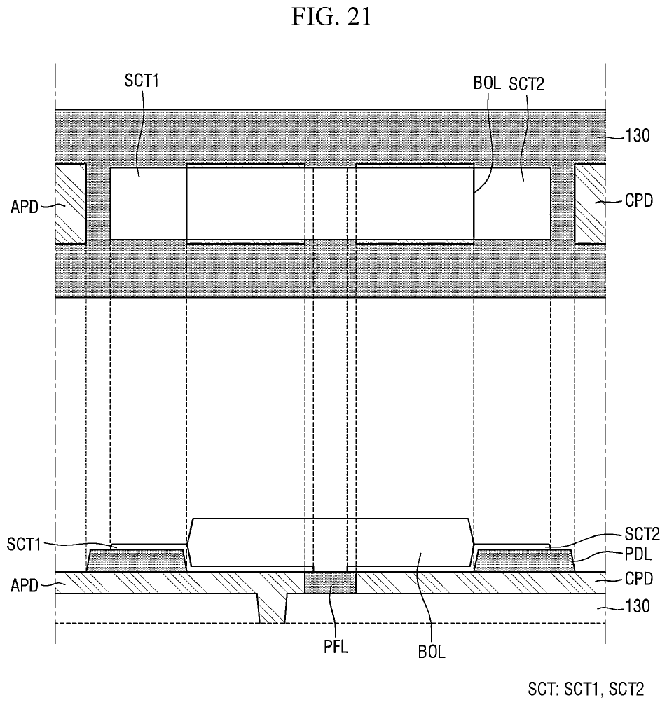

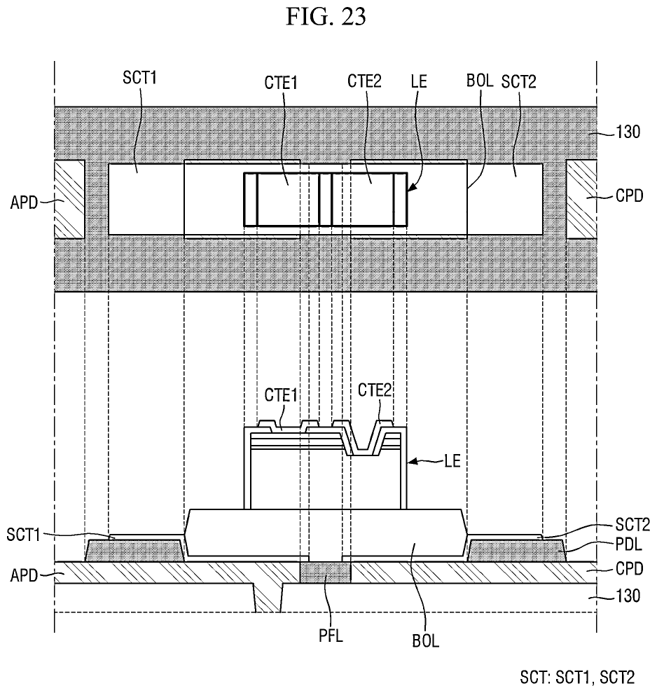

Then, referring to FIGS. 21 and 23, a plurality of light-emitting elements LE arranged on the support film SPF1 are transferred onto the second planarization layer 130.

For example, an organic pattern layer BOL located within the opening defined by the bank PDL is formed. At this stage, the organic pattern layer BOL is not cured and is in a fluid state and may be called a temporary adhesive layer.

Next, the support substrate SPF1 is aligned on the substrate 110. The third semiconductor layer SEM3 of the light-emitting element LE is aligned on the support substrate SPF1 to be located on the organic pattern layer BOL. The light-emitting element LE is located so that the first contact electrode CTE1 and the second contact electrode CTE2 face the top. The first contact electrode CTE1 may be located close to the first pad electrode APD, and the second contact electrode CTE2 may be located close to the second pad electrode CPD.

Then, the substrate 110 and the support substrate SPF1 are bonded together. For example, the third semiconductor layer SEM3 of the light-emitting element LE on the support substrate SPF1 may contact the organic pattern layer BOL. Next, the organic pattern layer BOL is cured by applying heat and pressure to the organic pattern layer BOL. Accordingly, the light-emitting element LE is bonded to the organic pattern layer BOL by curing the organic pattern layer BOL. The heat and pressure required in the process of bonding the organic pattern layer BOL are lower than those required in the eutectic bonding process. For example, while the eutectic bonding process is a relatively high temperature process of about 200 degrees Celsius to about 400 degrees Celsius, the organic-material-curing process may be a relatively low temperature process of about 80 degrees Celsius to about 200 degrees Celsius. Accordingly, the light-emitting element LE may be bonded to the substrate 110 at a relatively lower temperature and pressure, as compared to the eutectic bonding process.

Thereafter, the support substrate SPF1 is separated from the plurality of light-emitting elements LE. After applying ultraviolet rays or heat to the support substrate SPF1 to reduce the adhesive strength of the adhesive layer of the relay substrate SPF2, the support substrate SPF1 may be physically or naturally separated from the plurality of light-emitting elements LE.

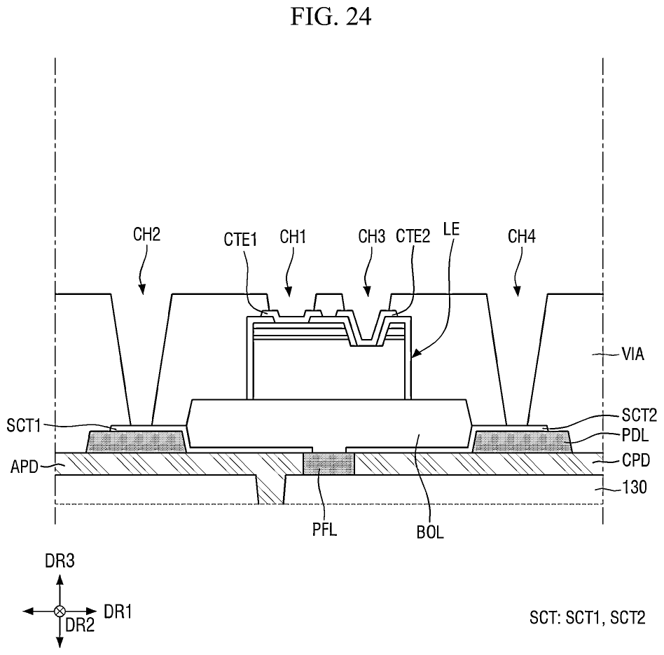

Next, referring to FIG. 24, a via layer VIA having a plurality of contact holes CH1, CH2, CH3, and CH4 may be formed.

The via layer VIA may be formed to be higher than the height of the light-emitting element LE. The via layer VIA may be formed so that the entire light-emitting element LE is covered. The via layer VIA may be applied using a solution process, such as spin coating or inkjet printing.

Next, a plurality of contact holes CH1, CH2, CH3, and CH4 may be formed in the via layer VIA through an etching process using a mask.

The first contact hole CH1 exposes the first contact electrode CTE1, the second contact hole CH2 exposes the first reflective electrode SCT1, the third contact hole CH3 exposes the second contact electrode CTE2, and the fourth contact hole CH4 exposes the second reflective electrode SCT2.

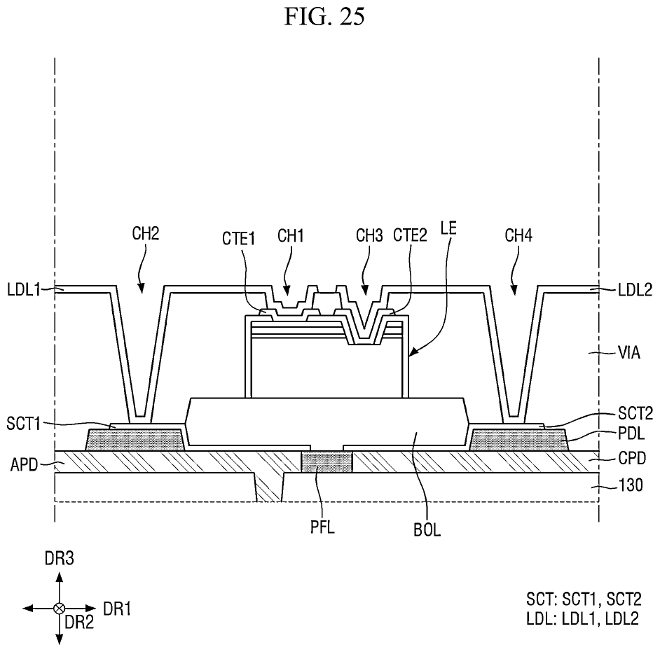

Next, referring to FIG. 25, a first lead line LDL1 and a second lead line LDL2 are formed on the via layer VIA.

For example, a lead line material layer may be applied on the via layer VIA, and the lead line material layer may be spaced apart from each other by an etching process using a mask to form the first lead line LDL1 and the second lead line LDL2. The first lead line LDL1 is formed along the first contact hole CH1 and the second contact hole CH2, and the second lead line LDL2 is formed along the third contact hole CH3 and the fourth contact hole CH4. Accordingly, the first lead line LDL1 contacts the first contact electrode CTE1 exposed by the first contact hole CH1, and contacts the first reflective electrode SCT1 exposed by the second contact hole CH2. Further, the second lead line LDL2 contacts the second contact electrode CTE2 exposed by the third contact hole CH3, and contacts the second reflective electrode SCT2 exposed by the fourth contact hole CH4. Accordingly, the first contact electrode CTE1 is electrically connected to the first pad electrode APD, and the second contact electrode CTE2 is electrically connected to the second pad electrode CPD.

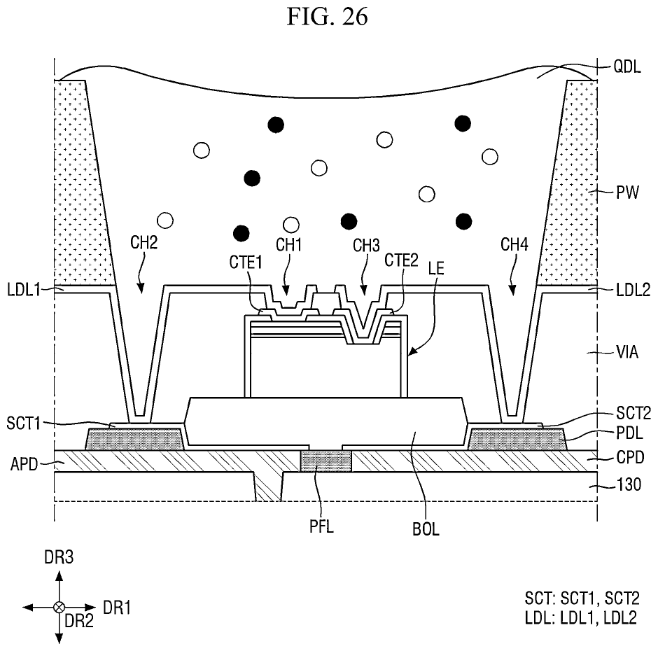

Next, referring to FIG. 26, an organic material is applied on the via layer VIA and patterned to form a partition wall PW.

The organic material is applied on the via layer VIA and patterned to form the partition wall PW. A plurality of openings may be formed to correspond to the first light-emitting area EA1. In one or more embodiments, other openings are also formed to correspond to other light-emitting areas.

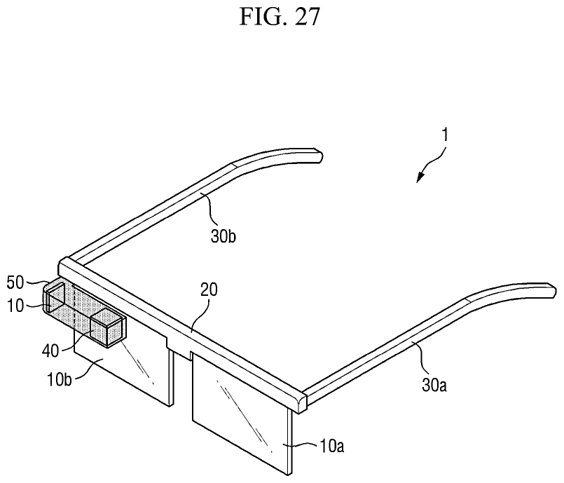

FIG. 27 is a diagram illustrating a virtual reality device including a display device according to one or more embodiments. FIG. 27 illustrates a virtual reality device 1 in which the display device 10 according to one or more embodiments is used.

Referring to FIG. 27, the virtual reality device 1 according to one or more embodiments may be a device in a form of glasses. The virtual reality device 1 according to one or more embodiments may include a display device 10, a left-eye lens 10a, a right-eye lens 10b, a support frame 20, left and right legs 30a and 30b, a reflective member 40, and a display device housing 50.

FIG. 27 illustrates the virtual reality device 1 including the two legs 30a and 30b. However, the disclosure is not limited thereto. The virtual reality device 1 according to one or more embodiments may be used in a head-mounted display including a head-mounted band that may be mounted on a head instead of the legs 30a and 30b. For example, the virtual reality device 1 according to one or more embodiments may not be limited to FIG. 27, and may be applied in various forms and in various electronic devices.

The display device housing 50 may receive the display device 10 and the reflective member 40. An image displayed on the display device 10 may be reflected from the reflective member 40 and provided to a user's right eye through the right-eye lens 10b. Thus, the user may view a virtual reality image displayed on the display device 10 via the right eye.

FIG. 27 illustrates that the display device housing 50 is located at a right end of the support frame 20. However, one or more embodiments of the disclosure is not limited thereto. For example, the display device housing 50 may be located at a left end of the support frame 20. In this case, the image displayed on the display device 10 may be reflected from the reflective member 40 and provided to the user's left eye via the left-eye lens 10a. Thus, the user may view the virtual reality image displayed on the display device 10 via the left eye. As another example, the display device housing 50 may be located at each of the left end and the right end of the support frame 20. In this case, the user may view the virtual reality image displayed on the display device 10 via both the left eye and the right eye.

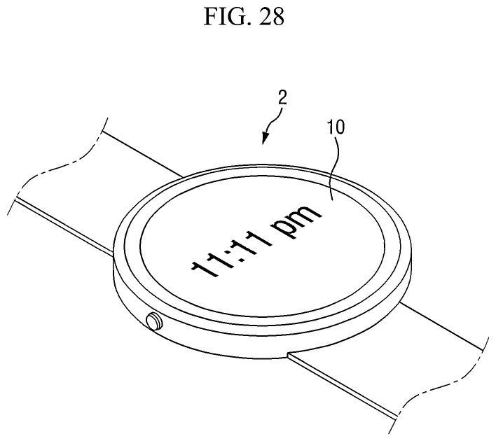

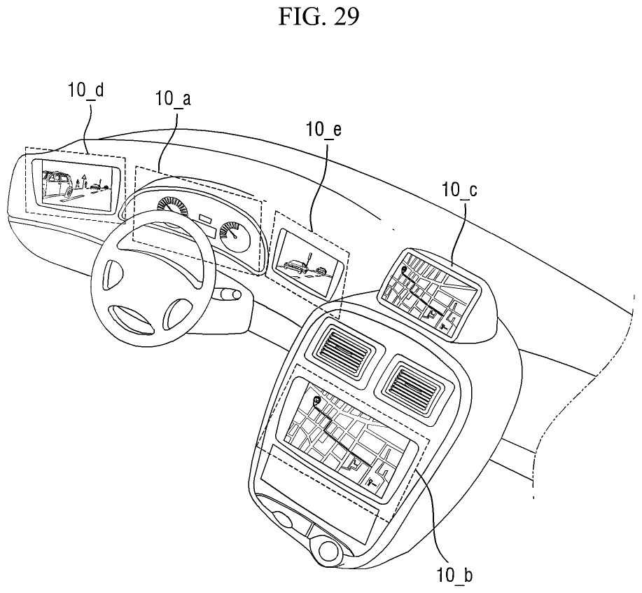

FIG. 28 is a diagram illustrating a smart device including a display device according to one or more embodiments.

Referring to FIG. 28, a display device 10 according to one or more embodiments may be applied to a smart watch 2 as one of smart devices.

FIG. 29 is a diagram illustrating a vehicle including a display device according to one or more embodiments. FIG. 29 illustrates a vehicle in which display devices according to one or more embodiments are used.

Referring to FIG. 29, the display devices 10_a, 10_b, and 10_c according to one or more embodiments may be applied to the dashboard of the vehicle, applied to the center fascia of the vehicle, or applied to a CID (Center Information Display) located on the dashboard of the vehicle. Further, each of the display devices 10_d and 10_e according to one or more embodiments may be applied to each room mirror display that replaces each of side-view mirrors of the vehicle.

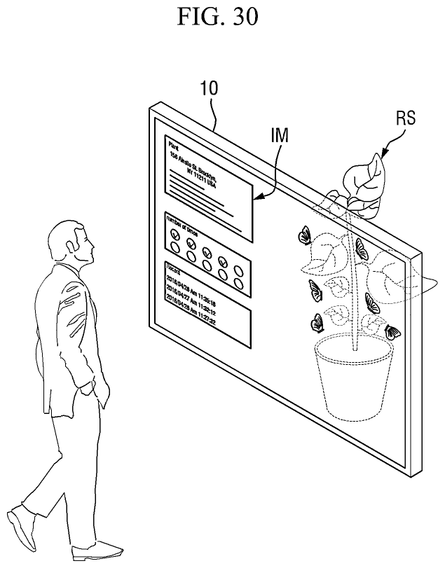

FIG. 30 is a diagram illustrating a transparent display device including a display device according to one or more embodiments.

Referring to FIG. 30, a display device according to one or more embodiments may be applied to a transparent display device. The transparent display device may transmit light therethrough while displaying an image IM thereon. Therefore, a user located in front of the transparent display device may not only view the image IM displayed on the display device 10, but also view an object RS or a background located in rear of the transparent display device. In case that the display device 10 is applied to the transparent display device, the substrate 110 of the display device 10 may include a light-transmitting portion that may transmit light therethrough or may be made of a material that may transmit light therethrough.

In concluding the detailed description, those skilled in the art will appreciate that many variations and modifications can be made to the embodiments without substantially departing from the aspects of the disclosure. Therefore, the disclosed embodiments of the disclosure are used in a generic and descriptive sense only and not for purposes of limitation.

What is claimed is:

1. A display device comprising:
a substrate comprising a first pad electrode and a second pad electrode;
a bank defining a first opening above the substrate, and exposing a portion of the first pad electrode and a portion of the second pad electrode through the first opening;
an inter-electrode planarization layer between the first pad electrode and the second pad electrode;
a first reflective electrode extending from the bank to the inter-electrode planarization layer along the first pad electrode;
a second reflective electrode extending from the bank to the inter-electrode planarization layer along the second pad electrode;
an organic pattern layer in the first opening;
a light-emitting element above the organic pattern layer, and having a first contact electrode and a second contact electrode on a top surface thereof;
a via layer covering the light-emitting element, and defining contact holes;
a first lead line above the via layer, and electrically connecting the first contact electrode and the first reflective electrode; and
a second lead line above the via layer, and electrically connecting the second contact electrode and the second reflective electrode.

2. The display device of claim 1, wherein the inter-electrode planarization layer and the bank have a same thickness.

3. The display device of claim 2, wherein the inter-electrode planarization layer and the bank comprise a same material.

4. The display device of claim 3, wherein the inter-electrode planarization layer and the bank comprise a light-blocking material.

5. The display device of claim 2, wherein the first pad electrode and the second pad electrode are spaced apart from each other on a same plane, and protrude outwardly from the light-emitting element in plan view.

6. The display device of claim 2, wherein the inter-electrode planarization layer has a same height as the first pad electrode and the second pad electrode.

7. The display device of claim 2, wherein a height of the inter-electrode planarization layer is greater than a height of the first pad electrode and the second pad electrode.

8. The display device of claim 7, wherein a top surface of the inter-electrode planarization layer contacts the organic pattern layer, and
wherein a roughness of the top surface of the inter-electrode planarization layer is greater than a roughness of another surface of the inter-electrode planarization layer.

9. The display device of claim 1 wherein the light-emitting element comprises a third semiconductor layer contacting the organic pattern layer, a second semiconductor layer, an active layer, a first semiconductor layer, and an element-insulating layer,
wherein the element-insulating layer surrounds the third semiconductor layer, the second semiconductor layer, the active layer, the first semiconductor layer, and the top surface of the light-emitting element, and defines a second opening and a third opening,
wherein the first contact electrode is electrically connected to the first semiconductor layer through the second opening, and
wherein the second contact electrode is electrically connected to the second semiconductor layer through the third opening.

10. The display device of claim 1, wherein a width of the organic pattern layer is greater than a width of the light-emitting element.

11. The display device of claim 10, wherein the organic pattern layer overlaps the inter-electrode planarization layer, does not overlap the bank, and directly contacts the inter-electrode planarization layer.

12. The display device of claim 1, further comprising:
a partition wall above the via layer, the first lead line, and the second lead line, and defining a light-emitting area; and
a wavelength conversion layer in the light-emitting area, and filling the contact holes in the via layer.

13. The display device of claim 12, further comprising a capping layer, an overcoat layer, and a color filter layer sequentially above the wavelength conversion layer and the partition wall.

14. A method of manufacturing display device comprising:
providing a substrate on which a first pad electrode and a second pad electrode are located;
forming a bank above the substrate, the bank defining a first opening exposing a portion of the first pad electrode and a portion of the second pad electrode;
forming an inter-electrode planarization layer above the substrate between the first pad electrode and the second pad electrode;
forming a first reflective electrode extending from the bank to the inter-electrode planarization layer along the first pad electrode;
forming a second reflective electrode extending from the bank to the inter-electrode planarization layer along the second pad electrode;
applying an organic pattern material layer in the first opening,
placing a light-emitting element on the organic pattern material layer;
curing the organic pattern material layer to form an organic pattern layer, and to bond the light-emitting element to the organic pattern layer;
forming a via layer covering the light-emitting element, and defining contact holes;
forming a first lead line above the via layer to electrically connect a first contact electrode and the first reflective electrode; and
forming a second lead line above the via layer to electrically connect a second contact electrode and the second reflective electrode.

15. The method of claim 14, wherein forming the bank and forming the inter-electrode planarization layer comprises:
coating an organic material layer above the substrate; and
etching the organic material layer to form the bank and the inter-electrode planarization layer by using a mask.

16. The method of claim 15, wherein the organic material layer comprises a light-blocking material.

17. The method of claim 15, wherein coating the organic material layer comprises applying the organic material layer to a same thickness as the first pad electrode and the second pad electrode.

18. The method of claim 15, further comprising performing a descum or ashing process on a top surface of the bank and the inter-electrode planarization layer to increase a roughness of the top surface of the bank and the inter-electrode planarization layer.

19. The method of claim 14, wherein the light-emitting element comprises a third semiconductor layer, a second semiconductor layer, an active layer, and a first semiconductor layer stacked sequentially,
wherein the light-emitting element comprises an element-insulating layer,
wherein the element-insulating layer surrounds the third semiconductor layer, the second semiconductor layer, the active layer, the first semiconductor layer, and a top surface of the light-emitting element, and defines a second opening and a third opening,
wherein the first contact electrode is electrically connected with the first semiconductor layer through the second opening, and
wherein the second contact electrode is electrically connected with the second semiconductor layer through the third opening.

20. The method of claim 14, further comprising:
forming a partition wall above the via layer, the first lead line, and the second lead line, and defining a light-emitting area;
forming a wavelength conversion layer in the light-emitting area; and
forming an overcoat layer and a color filter layer sequentially arranged above the partition wall and the wavelength conversion layer.
